(19) United States
(12) Patent Application Publication
(10) Pub. No.: US 2025/0259969 A1
(43) Pub. Date: Aug. 14, 2025

(54) HIGH BANDWIDTH NON-VOLATILE MEMORY

(71) Applicant: SanDisk Technologies LLC, Austin, TX (US)

(72) Inventors: Yan Li, Milpitas, CA (US); James Kai, Santa Clara, CA (US); Mohan Dunga, Santa Clara, CA (US); Nagesh Vodrahalli, Los Altos, CA (US)

(21) Appl. No.: 18/739,168

(22) Filed: Jun. 10, 2024

Related U.S. Application Data
(60) Provisional application No. 63/553,102, filed on Feb. 13, 2024.

(51) Int. Cl. H01L 25/065; G11C 11/419; H10B 80/00

(52) U.S. Cl. CPC H01L 25/0657; G11C 11/419; H10B 80/00; H01L 2225/06541

(57) ABSTRACT

A non-volatile memory apparatus includes a stack of memory dies with multiple layers. Each layer has multiple memory die, and the stack includes separate parallel through silicon vias (TSVs) for each memory die. The non-volatile memory apparatus also includes a memory controller in electrical communication with the separate parallel TSVs for each memory die and configured to perform a high bandwidth read process for data stored in the stack across all or multiple of the memory dies.

### CROSS-REFERENCE TO RELATED APPLICATION

This application claims priority to and the benefit of U.S. Provisional App. No. 63/553,102, filed Feb. 13, 2024, entitled “NON-VOLATILE MEMORY WITH HIGH BANDWIDTH READ,” the entire contents of which is herein incorporated by reference.

### BACKGROUND

### 1. Field

The present disclosure is related generally to non-volatile memory and, more particularly to improved memory devices that are optimized to operate at very high read performance and with a very low power consumption.

### 2. Related Art

Semiconductor memory is widely used in various electronic devices such as cellular telephones, digital cameras, personal digital assistants, medical electronics, mobile computing devices, servers, solid state drives, non-mobile computing devices and other devices. Semiconductor memory may be non-volatile memory or volatile memory. A non-volatile memory allows information to be stored and retained even when the non-volatile memory is not connected to a source of power (e.g., a battery).

Non-volatile memory devices include one or more memory chips having multiple arrays of memory cells. The memory arrays may have associated decoders and circuits for performing read, write, and erase operations. Memory cells within the arrays may be arranged in horizontal rows and vertical columns. Each row may be addressed by a word line, and each column may be addressed by a bit line. Data may be loaded into columns of the array using a series of data busses. Each column may hold a predefined unit of data, for instance, a word encompassing two bytes of information.

In some applications, semiconductor memory is used to store very large amounts of data that are repeatedly accessed (e.g., read) very rapidly. For example, in some machine learning applications, large language models that include a terabyte (or more) of data must be stored in memory and retrieved at a very high data rate. Accordingly, such applications require very high bandwidth and low power.

Currently, high bandwidth volatile memory devices (e.g., DRAM memory devices called “high bandwidth memory” or “HBM”) are used for such applications. Non-volatile memory (e.g., NAND) is significantly less expensive than DRAM, but the bandwidth of conventional NAND memory devices is too low, and the power consumption of conventional NAND memory devices is too high to provide a viable alternative to HBM devices. Therefore, there is a need to provide high bandwidth, low power non-volatile memory.

### SUMMARY

One aspect of the present disclosure is related to a non-volatile memory apparatus. The non-volatile memory apparatus includes a stack of memory dies with multiple layers. Each layer has multiple memory die, and the stack includes separate parallel through silicon vias (TSVs) for each memory die. The non-volatile memory apparatus also includes a memory controller in electrical communication with the separate parallel TSVs for each memory die and configured to perform a high bandwidth read process for data stored in the stack across all or multiple of the memory dies.

According to another aspect of the present disclosure, an interposer is connected to the separate parallel TSVs for each memory die and to the memory controller.

According to yet another aspect of the present disclosure, each memory die comprises multiple planes, and groups of planes form banks. Each memory die also has multiple input/output (I/O) circuits such that there is one I/O circuit per bank. The stack includes separate parallel TSVs for each I/O circuit of each memory die. A memory controller includes separate input paths for each memory die in communication with respective TSVs and one or more static random access memory (SRAM) buffers connected to the separate input paths.

According to still another aspect of the present disclosure, the memory controller includes separate input paths for each memory die in communication with respective TSVs. There also are separate and parallel error correction code (ECC) processing paths for each memory die connected to the separate input paths to perform ECC decoding concurrently for each memory die and one or more static random access memory (SRAM) buffers connected to the and parallel ECC processing paths.

According to a further aspect of the present disclosure, each of the memory dies include an extra bank. The memory controller is configured to perform a refresh of data to the extra bank during idle time or concurrently with the high bandwidth read process.

According to yet a further aspect of the present disclosure, the stack includes an extra layer. The memory controller is configured to perform a refresh of data to the extra layer during idle time or concurrently with the high bandwidth read process.

According to still a further aspect of the present disclosure, each memory die comprises at least sixteen planes that are grouped into at least four banks, and each bank includes an input/output (I/O) circuit for communicating data between the planes and the memory controller.

Another aspect of the present disclosure is related to a method of operating a non-volatile memory apparatus. The method includes the step of preparing a stack of memory dies comprising multiple layers. Each layer comprises multiple memory die, the stack includes separate parallel through silicon vias (TSVs) for each memory die. An interposer is connected to the separate parallel TSVs for each memory die. A memory controller is connected to the interposer. The method continues with the step of performing a high bandwidth read process for data stored in the stack across all or multiple of the memory dies.

According to another aspect of the present disclosure, each memory die comprises multiple planes, and groups of planes form banks. Each memory die has multiple input/output (I/O) circuits such that there is one I/O circuit per bank. The stack includes separate parallel TSVs for each I/O circuit of each memory die.

According to yet another aspect of the present disclosure, the controller includes separate input paths for each memory die in communication with respective TSVs and one or more static random access memory (SRAM) buffers connected to the separate input paths.

According to still another aspect of the present disclosure, the controller includes separate input paths for each memory die in communication with respective TSVs, separate and parallel error correction code (ECC) processing paths for each memory die connected to the separate input paths to perform ECC decoding concurrently for each memory die. One or more static random access memory (SRAM) buffers are also connected to the and parallel ECC processing paths.

According to a further aspect of the present disclosure, each of the memory dies includes an extra bank. The memory controller is configured to perform a refresh of data to the extra bank during idle time or concurrently with the high bandwidth read process.

According to yet a further aspect of the present disclosure, the stack includes an extra layer. The memory controller is configured to perform a refresh of data to the extra layer during idle time or concurrently with the high bandwidth read process.

According to still a further aspect of the present disclosure, each memory die comprises at least sixteen planes that are grouped into at least four banks. Each bank includes an input/output (I/O) circuit for communicating data between the planes and the memory controller.

Yet another aspect of the present disclosure is related to a computing system that includes a processor unit and a plurality of high bandwidth flash packages in electrical communication with the processor unit. Each of the high bandwidth flash packages includes a stack of memory dies comprising multiple layers, each layer comprising multiple memory die. The stack includes separate parallel through silicon vias (TSVs) for each memory die. Each of the high bandwidth flash packages also includes an interposer connected to the separate parallel TSVs for each memory die. A memory controller connected to the interposer and is configured to perform a high bandwidth read process for data stored in the stack across all or multiple of the memory dies.

According to another aspect of the present disclosure, the high bandwidth flash packages include data related to large language model weight matrices.

According to yet another aspect of the present disclosure, each of the memory die comprises multiple planes and groups of planes form banks. Each memory die has multiple input/output (I/O) circuits such that there is one I/O circuit per bank. The stack includes separate parallel TSVs for each I/O circuit of each memory die.

According to another aspect of the present disclosure, the memory controller includes separate input paths for each memory die in communication with respective TSVs and one or more static random access memory (SRAM) buffers connected to the separate input paths.

According to yet another aspect of the present disclosure, the memory controller includes separate input paths for each memory die in communication with respective TSVs. Separate and parallel error correction code (ECC) processing paths are provided for each memory die connected to the separate input paths to perform ECC decoding concurrently for each memory die. One or more static random access memory (SRAM) buffers are connected to the and parallel ECC processing paths.

According to still another aspect of the present disclosure, each of the memory dies include an extra bank. The memory controller is configured to perform a refresh of data to the extra bank during idle time or concurrently with the high bandwidth read process.

### BRIEF DESCRIPTION OF THE DRAWINGS

These and other features and advantages of the subject disclosure will become more readily appreciated when considered in connection with the following description of the presently preferred embodiments, appended claims and accompanying drawings, in which:

FIG. 1 is a block diagram depicting one embodiment of a storage system.

FIG. 2A is a block diagram of one embodiment of a memory die.

FIG. 2B is a block diagram of one embodiment of an integrated memory assembly (also referred to as a memory die).

FIGS. 3A and 3B depict different embodiments of integrated memory assemblies.

FIG. 4A is a perspective view of a portion of one embodiment of a monolithic three dimensional memory structure.

FIG. 4B is a block diagram of one embodiment of a memory structure having four planes.

FIG. 4C depicts a top view of a portion of one embodiment of a block of memory cells.

FIG. 4D depicts a cross sectional view of a portion of one embodiment of a block of memory cells.

FIG. 4E depicts a cross sectional view of a portion of one embodiment of a block of memory cells.

FIG. 4F is a cross sectional view of one embodiment of a vertical column of memory cells.

FIG. 4G is a schematic of a plurality of NAND strings in multiple regions of a same block.

FIG. 5A depicts threshold voltage distributions.

FIG. 5B depicts threshold voltage distributions.

FIG. 5C depicts threshold voltage distributions.

FIG. 5D depicts threshold voltage distributions.

FIG. 6 is a flow chart describing one embodiment of a process for programming non-volatile memory.

FIG. 7 depicts a non-volatile memory system capable of performing a high bandwidth read process.

FIG. 8A is a block diagram of one layer of a stack of memory die.

FIG. 8B is a block diagram of one layer of a stack of memory die.

FIG. 9 is a block diagram depicting a partial floor plan for a memory die.

FIG. 10 is a block diagram depicting a partial floor plan for a memory die.

FIG. 11 is a block diagram depicting a partial floor plan for a memory die.

FIG. 12 is a block diagram depicting a partial floor plan for a memory die.

FIG. 13 is a block diagram depicting a partial floor plan for a memory die.

FIG. 14 is a flow chart describing one embodiment of a process for performing a high bandwidth read process.

FIG. 15A is a system level timing diagram for a high bandwidth read process.

FIG. 15B is a die level timing diagram for a high bandwidth read process.

FIG. 16 is a block diagram of a memory controller.

FIG. 17 is a block diagram depicting data flow at the memory controller during a high bandwidth read process.

FIG. 18 is a block diagram depicting error correction performed at the memory controller during a high bandwidth read process.

FIG. 19 is a block diagram depicting a partial floor plan for a memory die.

FIG. 20 is a block diagram depicting a partial floor plan for a memory die.

FIG. 21 is a flow chart describing one embodiment of a process for performing error correction during a high bandwidth read process.

FIG. 22 depicts a non-volatile memory system capable of performing data refresh in conjunction with a high bandwidth read process.

FIG. 23 depicts a block diagram of a memory controller performing a data refresh.

FIG. 24 is a block diagram depicting a partial floorplan for a memory die adapted to perform a data refresh.

FIG. 25 is a timing diagram for performing a data refresh.

FIG. 26 is a flow chart describing one embodiment of a process for performing a data refresh in conjunction with a high bandwidth read process.

FIG. 27 is a flow chart describing one embodiment of a process for performing a data refresh in conjunction with a high bandwidth read process.

FIG. 28 is a flow chart describing one embodiment of a process for performing a data refresh in conjunction with a high bandwidth read process.

FIG. 29 is a schematic view of an example computing system including a processing unit and a plurality of high bandwidth flash units that are constructed according the embodiments of the present disclosure.

### DETAILED DESCRIPTION OF THE ENABLING EMBODIMENT

A non-volatile memory is disclosed that is capable of performing a high bandwidth read process. On example use case is to deploy the non-volatile memory to store a trained model for an inference engine as part of an artificial intelligence application. Typically, the trained model is programmed into the non-volatile memory once and then read many times. To support the input needs of the inference engine, the process of reading the model must be performed at a high bandwidth. Typically, DRAM is used to store a trained model. However, non-volatile memory can be less expensive than DRAM. Therefore, deploying the non-volatile memory to store the trained model and being able to read the data for the model at the expected bandwidth allows for significant cost savings. According to an aspect of the present disclosure, a high bandwidth flash (HBF) device is provided that includes a stack of memory dies that are disposed in layers with each layer containing multiple dies. A plurality of parallel through silicon vias (TSVs) extend through the layers from the dies to an interposer. A memory controller is connected to the interposer and is configured to perform a high bandwidth rad process for data stored in the stack across the memory dies. These features are discussed in further detail below.

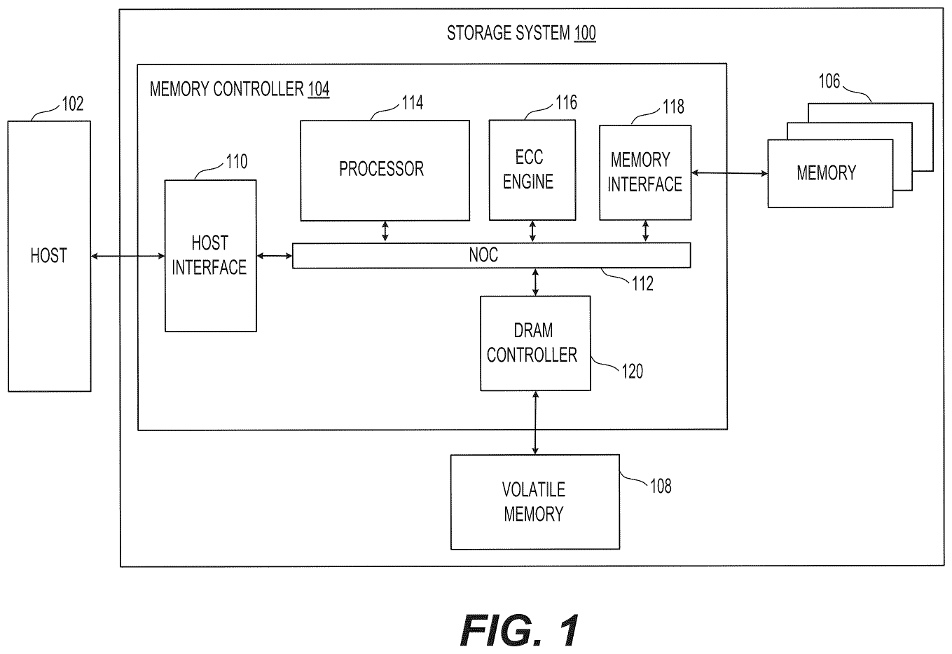

FIG. 1 is a block diagram of one embodiment of a storage system 100 that implements the proposed technology described herein. In one embodiment, the storage system 100 is a solid state drive (“SSD”). The storage system 100 also can be a memory card, a USB drive, or any other type of storage system. In other words, the proposed technology is not limited to any one type of memory system.

The storage system 100 is connected to a host 102, which can be a computer; server; electronic device (e.g., smart phone, tablet or other mobile device); appliance; or another apparatus that uses memory and has data processing capabilities. In some embodiments, the host 102 is separate from, but connected to, the storage system 100. In other embodiments, the storage system 100 is embedded within the host 102.

The components of the storage system 100 depicted in FIG. 1 are electrical circuits. The storage system 100 includes a memory controller 104 connected to non-volatile memory 106 and local high speed volatile memory 108 (e.g., DRAM). A local high speed volatile memory 108 is used by memory controller 104 to perform certain functions. For example, the local high speed volatile memory 108 stores logical to physical address translation tables (“L2P tables”).

The memory controller 104 includes a host interface 110 that is connected to and in communication with the host 102. In one embodiment, a host interface 110 implements an NVM Express (NVMe) over PCI Express (PCIe). Other interfaces can also be used, such as SCSI, SATA, etc. The host interface 110 also is connected to a network-on-chip (NOC) 112.

An NOC is a communication subsystem on an integrated circuit. The NOC's can span synchronous and asynchronous clock domains or use un-clocked asynchronous logic. NOC technology applies networking theory and methods to on-chip communications and brings notable improvements over conventional bus and crossbar interconnections. The NOC improves the scalability of systems on a chip (SoC) and the power efficiency of complex SoCs compared to other designs.

The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, the NOC 112 can be replaced by a bus.

Connected to and in communication with NOC 112 is a processor 114, an ECC engine 116, a memory interface 118, and a DRAM controller 120. The DRAM controller 120 is used to operate and communicate with local high speed volatile memory 108 (e.g., DRAM). In other embodiments, the local high speed volatile memory 108 can be SRAM or another type of volatile memory.

The ECC engine 116 performs error correction services. More specifically, the ECC engine 116 performs data encoding and decoding, as per an implemented ECC technique. In one embodiment, the ECC engine 116 includes an electrical circuit that is programmed by software. For example, the ECC engine 116 can include a processor that can be programmed. In other embodiments, the ECC engine 116 includes a custom and dedicated hardware circuit without any software. In another embodiment, the function of ECC engine 116 is implemented by the processor 114.

In operation, the processor 114 performs the various controller memory operations, such as programming, erasing, reading, and memory management processes. In one embodiment, the processor 114 is programmed by firmware. In other embodiments, the processor 114 is a custom and dedicated hardware circuit without any software. The processor 114 also implements a translation module, as a software/firmware process or as a dedicated hardware circuit.

In many systems, the non-volatile memory is addressed internally to the storage system using physical addresses associated with one or more memory dies. However, the host system will use logical addresses to address the various memory locations. This enables the host to assign data to consecutive logical addresses, while the storage system is free to store the data as it wishes among the locations of the one or more memory dies. To implement this system, the memory controller 104 (e.g., the translation module) performs address translation between the logical addresses used by the host and the physical addresses used by the memory dies.

One example implementation is to maintain tables (i.e., the L2P tables referenced above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 108 cannot hold all of the L2P tables. In such a case, the entire set of L2P tables are stored in non-volatile memory 106 and a subset of the L2P tables are cached (L2P cache) in the local high speed volatile memory 108.

The memory interface 118 communicates with the non-volatile memory 106. In one embodiment, the memory interface provides a Toggle Mode interface. However, other interfaces also can be used. In some example implementations, the memory interface 118 (or another portion of the controller 104) implements a scheduler and buffer for transmitting data to and receiving data from one or more memory die.

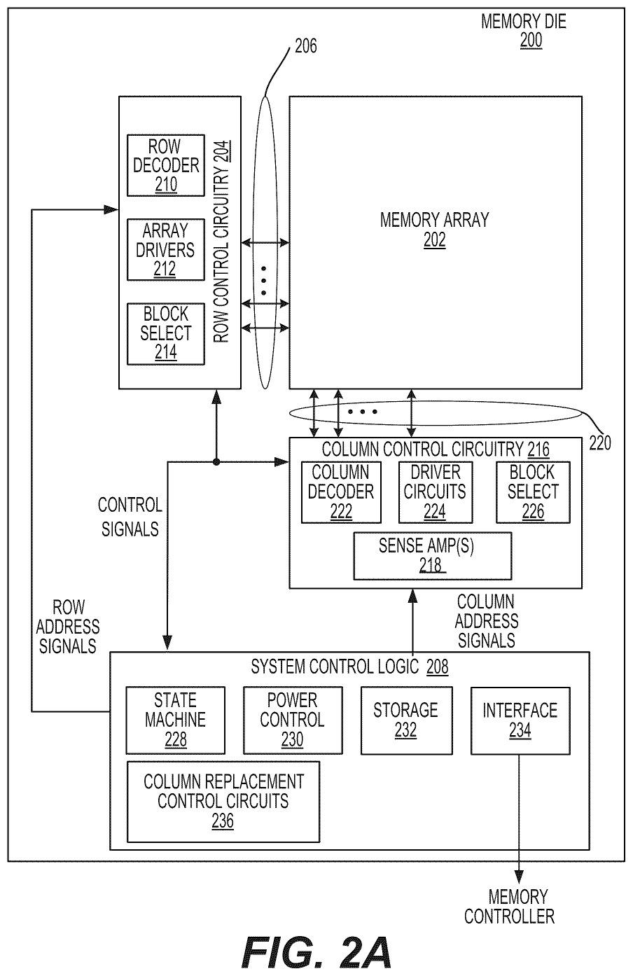

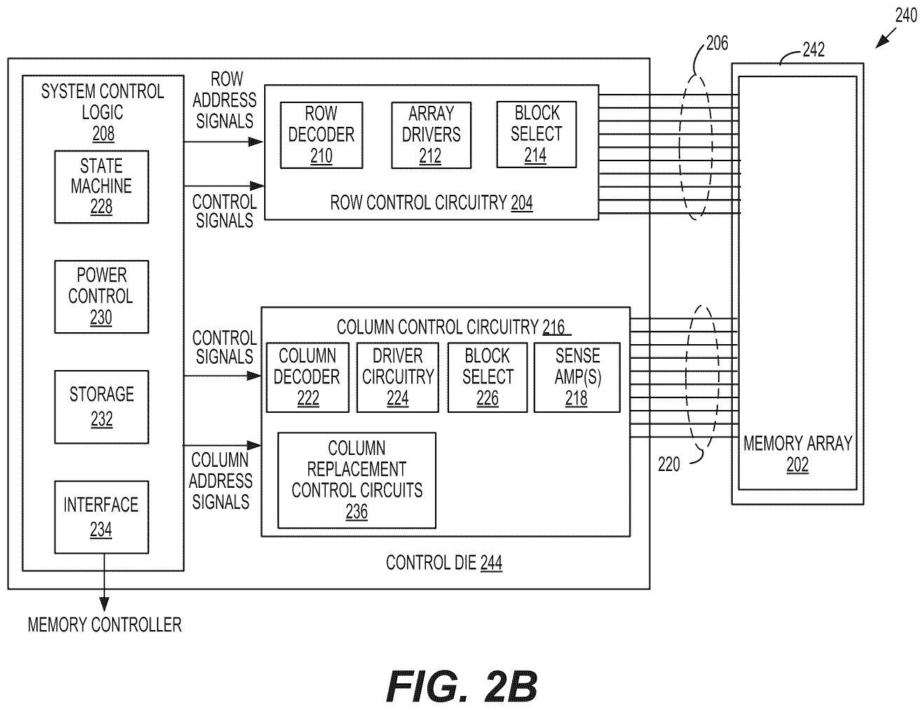

In one embodiment, the non-volatile memory 106 includes one or more memory die. FIG. 2A is a functional block diagrams of one embodiment of a memory die 200 that includes the non-volatile memory 106. Each of the one or more memory dies of non-volatile memory 106 can be implemented as the memory die 200 of FIG. 2A. The components depicted in FIG. 2A are electrical circuits.

The memory die 200 includes a memory array 202 that can include non-volatile memory cells, as described in further detail below. The memory array 202 includes a plurality of layers of word lines that are organized as rows, and a plurality of layers of bit lines that are organized as columns. However, other orientations can also be implemented.

The memory die 200 also includes row control circuitry 204, whose outputs 206 are connected to respective word lines of the memory array 202. In operation, the row control circuitry 204 receives a group of M row address signals and one or more various control signals from a system control logic circuit 208 and may include such circuits as row decoders 210, array terminal drivers 212, and block select circuitry 214 for both reading and writing (programming) operations.

The row control circuitry 204 also may include read/write circuitry. The memory die 200 also includes column control circuitry 216 including sense amplifier(s) 218 whose input/outputs 220 are connected to respective bit lines of the memory array 202. Although only a single block is shown for memory array 202, the memory die 200 can include multiple arrays that can be individually accessed.

The column control circuitry 216 receives a group of N column address signals and one or more various control signals from system control logic 208. The column control circuitry 216 may also include such circuits as column decoders 222; array terminal receivers or driver circuits 224; block select circuitry 226; read/write circuitry; and I/O multiplexers.

The system control logic 208 receives data and commands from memory controller 104 (FIG. 1) and provides output data and status to host 102. In some embodiments, the system control logic 208, which includes one or more electrical circuits, includes a state machine 228 that provides die-level control of memory operations. In one embodiment, the state machine 228 is programmable by software. In other embodiments, the state machine 228 does not use software and is completely implemented in hardware (e.g., electrical circuits). In another embodiment, the state machine 228 is replaced by a micro-controller or microprocessor, either on or off the memory chip.

The system control logic 208 also can include a power control module 230 that controls the power and voltages supplied to the rows and columns of memory structure 202 during memory operations and may include charge pumps and regulator circuits for creating regulating voltages. The system control logic 208 also includes storage 232 (e.g., RAM, registers, latches, etc.), which may be used to store parameters for operating memory array 202.

In operation, commands and data are transferred between the memory controller 104 and the memory die 200 via a memory controller interface 234 (also referred to as a “communication interface”). The memory controller interface 234 is an electrical interface for communicating with memory controller 104. Examples of the memory controller interface 234 include a Toggle Mode Interface and an Open NAND Flash Interface (ONFI). Other I/O interfaces can also be used in other embodiments.

In an embodiment, the system control logic 208 also includes column replacement control circuits 236, described in more detail below.

In some embodiments, all elements of the memory die 200, including the system control logic 208, can be formed as part of a single die. In other embodiments, some or all of the system control logic 208 can be formed on a different die.

In one embodiment, the memory structure 202 comprises a three-dimensional memory array of non-volatile memory cells in which multiple memory levels are formed above a single substrate, such as a wafer. The memory structure 202 may include any type of non-volatile memory that are monolithically formed in one or more physical levels of memory cells having an active area disposed above a silicon (or other type of) substrate. In one example, the non-volatile memory cells include charge-trapping layers and are arranged in a plurality of vertical NAND strings.

In another embodiment, the memory structure 202 includes a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. For example, suitable technologies for the memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of memory structure 202 include two dimensional arrays, three dimensional arrays, cross-point arrays, stacked two dimensional arrays, vertical bit line arrays, and the like. One example of a ReRAM cross-point memory includes reversible resistance-switching elements arranged in cross-point arrays accessed by X lines and Y lines (e.g., word lines and bit lines).

In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, and the ferromagnetic layers are separated by a thin insulating layer. One of the two ferromagnetic layers is a permanent magnet that is set to a particular polarity, and the other ferromagnetic layer's magnetization can be changed to match that of an external field to store memory. The memory array may be built from a grid of such memory cells. In one embodiment, for programming, each memory cell lies between a pair of write lines that are arranged at right angles to each other, parallel to the cell, one above and one below the cell. When current is passed through the write lines, an induced magnetic field is created. MRAM based memory embodiments will be discussed in more detail below.

Phase change memory (PCM) exploits the unique behavior of chalcogenide glass. One embodiment uses a GeTe—Sb₂Te₃ super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

The technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) the memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202. However, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to system control logic 208, reduced availability of area can limit the available functions that can be implemented on-chip. Consequently, a basic trade-off in the design of a memory die for the storage system 100 may be the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based.

Elements such as the sense amplifier circuits, charge pumps, logic elements in a state machine, and other peripheral circuitry in the system control logic 208 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto a separately formed die that is then bonded together with another die. More specifically, the memory structure 202 can be formed on one die (referred to as the memory die) and some or all of the peripheral circuitry elements, including one or more control circuits, can be formed on a separate die (referred to as the control die). A memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology.

For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array.

The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 240. One or more integrated memory assemblies 240 may be used to implement the non-volatile memory 106 of storage system 100.

The integrated memory assembly 240 includes two types of semiconductor die (or more succinctly, “die”). The memory die 242 includes the memory structure 202 with the non-volatile memory cells. A control die 244 includes control circuitry 208, 216, and 204 (as described above). In some embodiments, the control die 244 is configured to connect to the memory structure 202 in the memory die 242. In some embodiments, the memory die 242 and control die 244 are bonded together.

FIG. 2B shows an example of the peripheral circuitry, including control circuits, formed in a peripheral circuit or control die 244 coupled to memory structure 202 formed in memory die 242. Common components are labelled similarly to FIG. 2A. The system control logic 208, the row control circuitry 204, and the column control circuitry 216 are located in the control die 244. In some embodiments, all or a portion of column control circuitry 216 and all or a portion of the row control circuitry 204 are located on memory die 242. In some embodiments, some of the circuitry in the system control logic 208 is located on the memory die 242.

The system control logic 208, the row control circuitry 204, and the column control circuitry 216 may be formed by a common process (e.g., CMOS process), so that adding elements and functions, such as the ECC controller, more typically found on a memory controller 104 may require few or no additional process steps, i.e., the same process steps used to fabricate controller 104 may also be used to fabricate the system control logic 208, the row control circuitry 204, and the column control circuitry 216.

Thus, while moving such circuits from a die such as the memory die 242 may reduce the number of steps needed to fabricate such a die, adding such circuits to a die such as control die 244 may not require many additional process steps. The control die 244 also could be referred to as a CMOS die, due to the use of CMOS technology to implement some or all of the control circuitry 204, 208, 216.

FIG. 2B shows column control circuitry 216, including the sense amplifier(s) 218, on control die 244 coupled to memory structure 202 on memory die 242 through electrical paths 220. The electrical paths 220 may provide an electrical connection between the column decoder 222, the driver circuitry 224, the block select 226, and the bit lines of the memory structure 202. In an embodiment, the column control circuitry 216 also includes column replacement control circuits 236, which are described in more detail below.

Electrical paths may extend from the column control circuitry 216 in the control die 244 through pads on the control die 244 that are bonded to corresponding pads of the memory die 242, which are connected to the bit lines of the memory structure 202. Each bit line of the memory structure 202 may have a corresponding one of the electrical paths 220, including a pair of bond pads, which connects to the column control circuitry 216.

Similarly, the row control circuitry 204, including the row decoder 210, the array drivers 212, and the block select 214 are coupled to the memory structure 202 through electrical paths 206. Each of the electrical paths 206 may correspond to a data containing word line, a dummy word line, or a select gate line. Additional electrical paths may also be provided between control die 244 and memory die 242.

For purposes of this document, the phrases “a control circuit,” “control circuitry,” or “one or more control circuits” can include any one of or any combination of the memory controller 104; the state machine 228; all or a portion of the system control logic 208; all or a portion of row control circuitry 204; all or a portion of column control circuitry 216; a microcontroller; a microprocessor; and/or other similar functioned circuits.

The control circuit can include hardware only or a combination of hardware and software (including firmware). For example, one or more controllers programmed by firmware to perform the functions described herein is one example of a control circuit. A control circuit can include a processor, FGA, ASIC, integrated circuit, or other type of circuit.

In some embodiments, there is more than one control die 244 and more than one memory die 242 in an integrated memory assembly 240. In some embodiments, the integrated memory assembly 240 includes a stack of multiple control dies 244 and multiple memory dies 242.

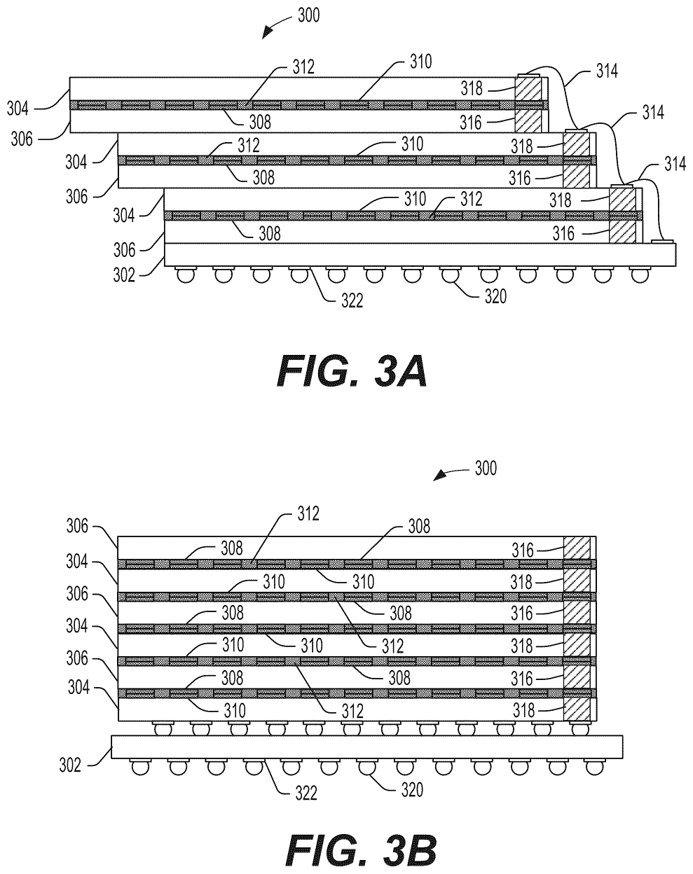

FIG. 3A depicts a side view of an embodiment of an integrated memory assembly 300 stacked on a substrate 302 (e.g., a stack including control die 304 and memory die 306). In this embodiment, the integrated memory assembly 300 has three control die 304 and three memory die 306. In some embodiments, there are more than three memory die 306 and more than three control die 304.

Each control die 304 is affixed (e.g., bonded) to at least one memory die 306. Some of the bond pads 308/310 are depicted, although there may be many more bond pads. A space between two die 306, 304 that are bonded together is filled with a solid layer 312, which may be formed from epoxy or other resin or polymer. This solid layer 312 protects the electrical connections between the die 306, 304 and further secures the die together. Various materials may be used as solid layer 312, but in some embodiments, it may be Hysol epoxy resin from Henkel Corp., having offices in California, USA.

Integrated memory assembly 300 may for example be stacked with a stepped offset, leaving the bond pads at each level uncovered and accessible from above. Wire bonds 314 connected to the bond pads connect control die 304 to substrate 302. A number of such wire bonds may be formed across the width of each control die 304 (i.e., into the page of FIG. 3A).

A memory die through silicon via (TSV) 316 may be used to route signals through each memory die 306. A control die TSV 318 may be used to route signals through each control die 304. The TSVs 316, 318 may be formed before, during or after formation of the integrated circuits in semiconductor die 306, 304. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, Solder balls 320 optionally may be affixed to contact pads 322 on a lower surface of substrate 302. Solder balls 320 may be used to couple integrated memory assembly 300 electrically and mechanically to a host device such as a printed circuit board. Solder balls 320 may be omitted where the integrated memory assembly 300 is to be used as an LGA package. Solder balls 320 may form a part of an interface between integrated memory assembly 300 and memory controller 104 (FIG. 1).

FIG. 3B depicts a side view of another embodiment of an integrated memory assembly 300 stacked on a substrate 302. The integrated memory assembly 300 of FIG. 3B has three control die 304 and three memory die 306. In some embodiments, there are many more than three memory die 306 and many more than three control die 304. In this example, each control die 304 is bonded to at least one memory die 306. Optionally, a control die 304 may be bonded to two or more memory die 306.

Some of the bond pads 308, 310 are depicted, but there may be many more bond pads than are illustrated. A space between two die 306, 304 that are bonded together is filled with a solid layer 312, which may be formed from epoxy or other resin or polymer. In contrast to the example in FIG. 3A, the integrated memory assembly 300 of FIG. 3B does not have a stepped offset. A memory die TSV 316 may be used to route signals through each memory die 306. A control die TSV 318 may be used to route signals through each control die 304.

As has been briefly discussed above, control die 304 and memory die 306 may be bonded together. Bond pads on each control die 304 and each memory die 306 may be used to bond the two die together. In some embodiments, the bond pads are bonded directly to each other, without solder or other added material, in a so-called Cu-to-Cu bonding process.

In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension.

As has been briefly discussed above, the control die 304 and the memory die 306 may be bonded together. Bond pads on each control die 304 and each memory die 306 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat also may be applied. In embodiments using cu-to-cu bonding, the bond pads may be about 5 μm square and spaced from each other with a pitch of 5 μm to 5 μm. Although this process is referred to herein as cu-to-cu bonding, this term also may apply even where the bond pads are formed of materials other than copper. When the area of bond pads is small, it may be difficult to bond the semiconductor die together. The size of and pitch between bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller (or greater) sizes and pitches.

Some embodiments may include a film on a surface of the control die 304 and the memory die 306. Where no such film is initially provided, a space between the die may be under filled with an epoxy or other resin or polymer. The under-fill material may be applied as a liquid which then hardens into a solid layer. This under-fill step protects the electrical connections between control die 304 and memory die 306, and further secures the die together. Various materials may be used as under-fill material, such as Hysol epoxy resin from Henkel Corp., having offices in California, U.S.A.

In a stack of control dies 304 and memory dies 306 (as depicted in FIG. 3A or FIG. 3B), the TSV's 316, 318 from various die 304, 306 of the stack can be shortened together to form a single bus or they can run in parallel with each other so that each die 304, 306 can be separately operated on and communicated with.

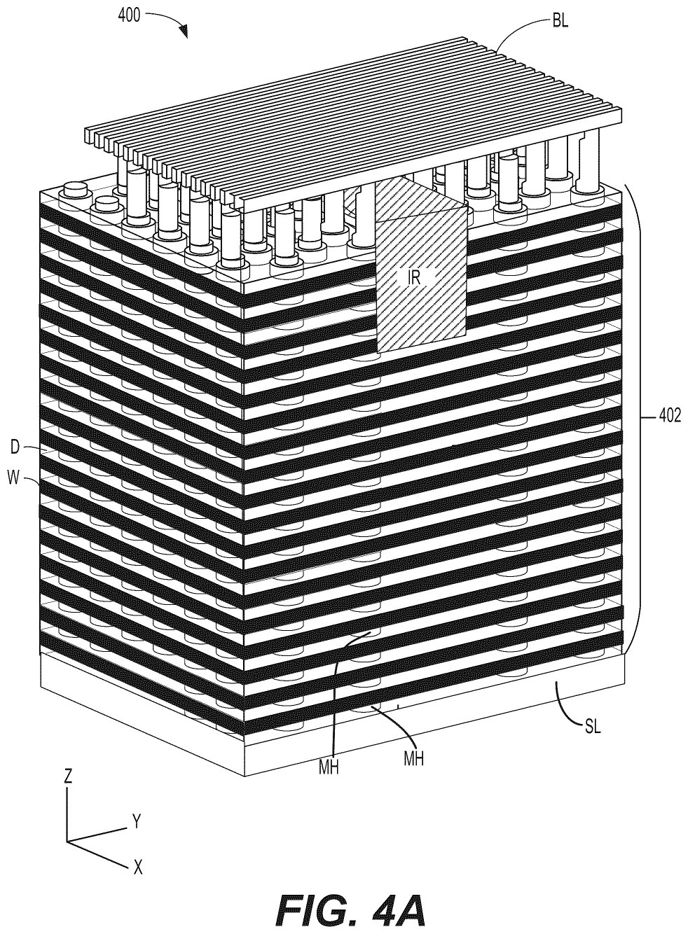

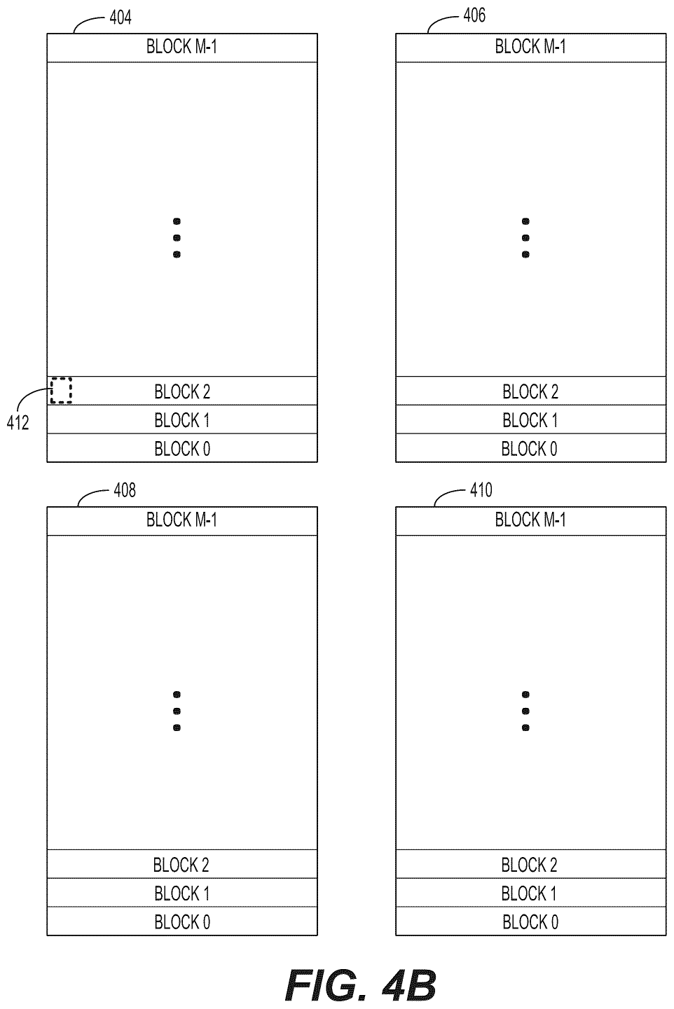

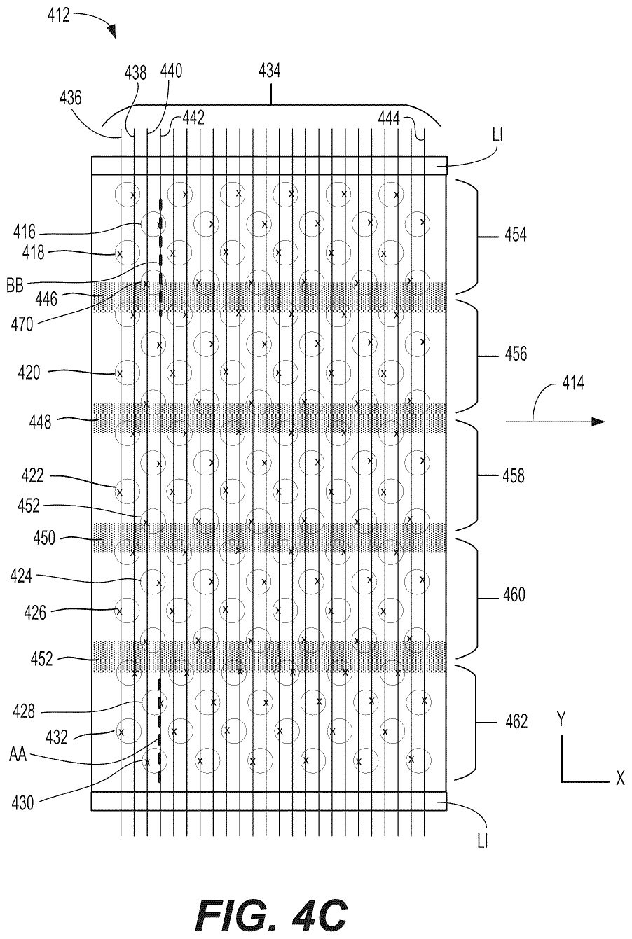

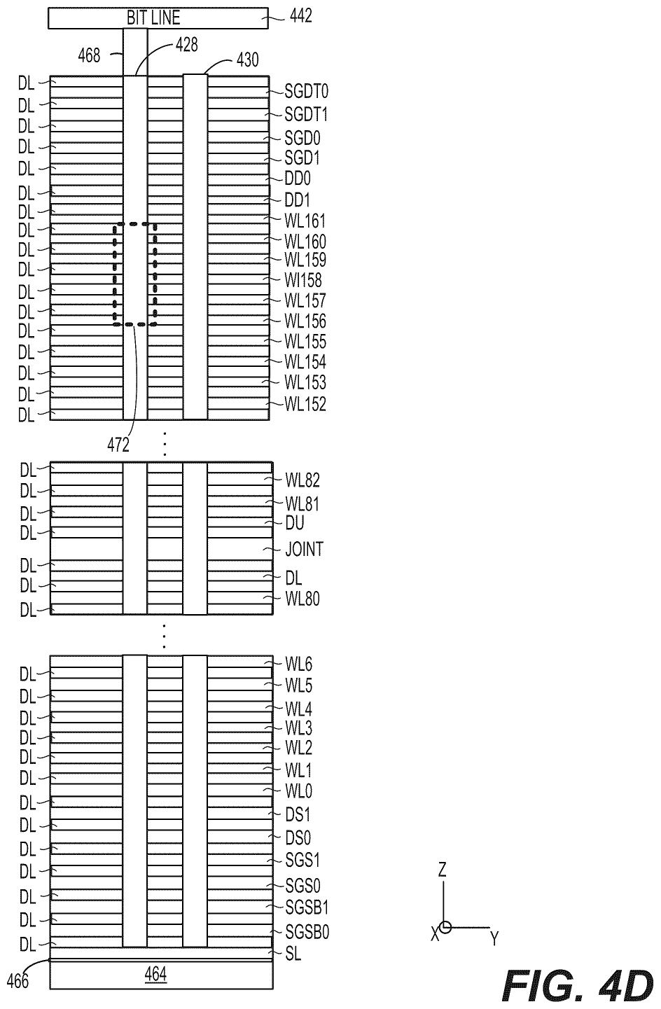

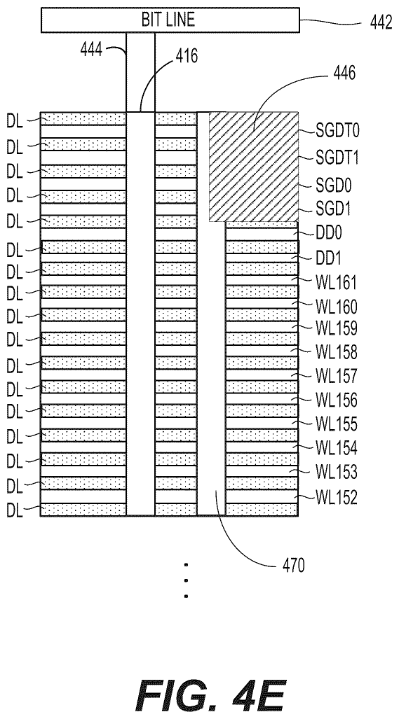

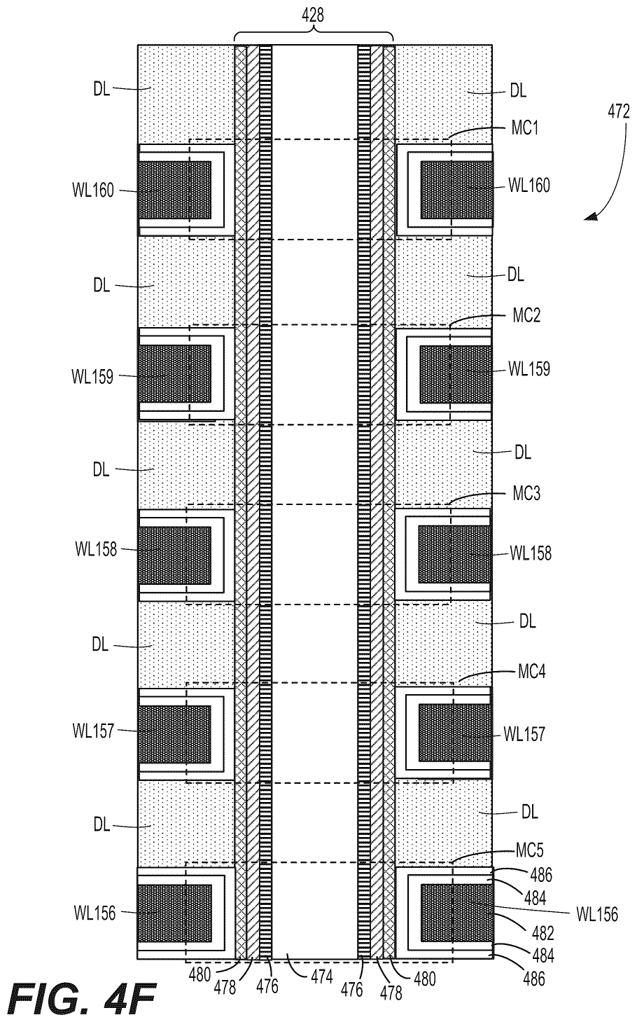

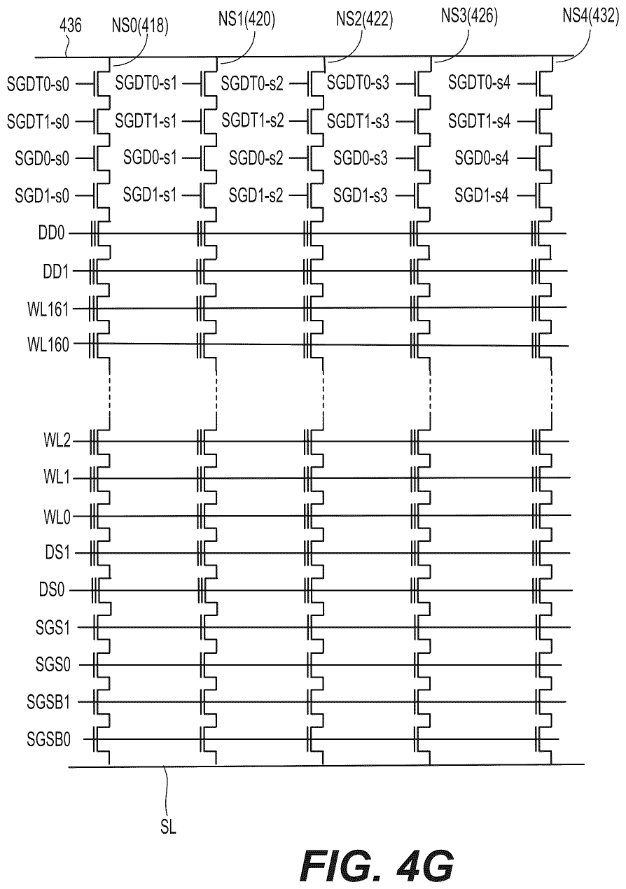

FIG. 4A is a perspective view of a portion of one example embodiment of a monolithic three dimensional memory array/structure included in memory structure 202, which includes a plurality non-volatile memory cells arranged as vertical NAND strings. For example, FIG. 4A shows a portion 400 of one block of memory. The structure depicted includes a set of bit lines BL positioned above a stack 402 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements.

As will be explained below, in one embodiment the alternating dielectric layers and conductive layers are divided into, for example, four or five (or a different number of) regions by isolation regions IR. FIG. 4A shows one isolation region IR separating two regions. Below the alternating dielectric layers and word line layers is a common source line layer SL. Memory holes are formed in the stack of alternating dielectric layers and conductive layers. For example, one of the memory holes is marked as MH. Note that in FIG. 4A, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells.

The non-volatile memory cells are arranged in memory holes, and each memory cell can store one or more bits of data, e.g., up to five bits of data per memory cell. More details of the three dimensional monolithic memory array that comprises memory structure 202 is provided below.

FIG. 4B is a block diagram explaining one example organization of memory structure 202, which is divided into four planes 404, 406, 408 and 410. Each plane is then divided into M blocks. In one example, each plane has about 2,000 blocks (“Block 0” to “Block M−1” with M being 2,000). However, different numbers of blocks and planes can also be used.

In one embodiment, a block of memory cells is a unit of erase. That is, all memory cells of a block are erased together. In other embodiments, the blocks can be divided into sub-blocks, each of which includes a plurality of word lines, and the sub-blocks can be the unit of erase. Memory cells also can be grouped into blocks for other reasons, such as to organize the memory structure to enable the signaling and selection circuits.

In some embodiments, a block represents groups of connected memory cells as the memory cells of a block share a common set of word lines. For example, the word lines for a block are all connected to all of the vertical NAND strings for that respective block. Although FIG. 4B shows four planes, each of which includes a plurality of blocks, more or fewer than four planes can be implemented in the memory structure 202. In some embodiments, the memory structure includes eight planes.

Each block typically is divided into one or more pages, with each page being a unit of programming/writing and a unit of reading. Other units of programming also can be used. In an embodiment, one or more pages of data are typically stored in one row of memory cells. For example, one or more pages of data may be stored in memory cells connected to a common word line. In an embodiment, a page includes data stored in all memory cells connected to a common word line within the block.

FIGS. 4C-4G depict an example three dimensional (“3D”) NAND structure that corresponds to the structure of FIG. 4A and can be used to implement the memory structure 202 of FIGS. 2A and 2B. FIG. 4C is a block diagram that depicts a top view of a portion 412 of Block 2 of plane 404. As can be seen from FIG. 4C, the block depicted in FIG. 4C extends in the direction of 414. In one embodiment, the memory array has many such layers with only the top layer being illustrated in FIG. 4C.

FIG. 4C depicts a plurality of circles that represent the memory holes, which are also referred to as vertical columns. Each of the memory holes/vertical columns includes multiple select transistors (also referred to as a select gate or selection gate) and multiple memory cells. In one embodiment, each memory hole/vertical column implements a NAND string. For example, FIG. 4C labels a subset of the memory holes/vertical columns/NAND strings 416, 418, 420, 422, 424, 426, 428, 430, and 432.

FIG. 4C also depicts a set of bit lines 434, including bit lines 436, 438, 440, 442, . . . 444. FIG. 4C shows twenty four bit lines because only a portion of the block is depicted. It is contemplated that more than twenty four bit lines connected to memory holes/vertical columns of the block. Each of the circles representing memory holes/vertical columns has an “x” to indicate its connection to one of the bit lines. For example, bit line 436 is connected to the memory holes/vertical columns 418, 420, 422, 426, and 432. The bit lines 436, 438, 440, 442 also are in electrical communication with all other blocks in a given plane.

The block depicted in FIG. 4C includes a set of isolation regions 446, 448, 450 and 452, which are formed of SiO₂. However, other dielectric materials also can be used. Isolation regions 446, 448, 450, and 452 serve to divide the top layers of the block into five regions. For example, the top layer depicted in FIG. 4C is divided into regions 454, 456, 458, 460, and 462.

In one embodiment, the isolation regions only divide the layers used to implement select gates so that NAND strings in different regions can be independently selected. In one example implementation, a bit line connects to one memory hole/vertical column/NAND string in each of regions 454, 456, 458, 460, and 462. In that implementation, each block has twenty-four rows of active columns and each bit line connects to five rows in each block.

In one embodiment, all of the five memory holes/vertical columns/NAND strings connected to a common bit line are connected to the same set of word lines; therefore, the system uses the drain side selection lines to choose one (or another subset) of the five to be subjected to a memory operation (program, verify, read, and/or erase).

FIG. 4C also shows Line Interconnects LI, which are metal connections to the source line SL from above the memory array. Line Interconnects LI are positioned adjacent regions 454 and 462.

Although FIG. 4C shows each region 454, 456, 458, 460, and 462 as having four rows of memory holes/vertical columns, five regions and twenty four rows of memory holes/vertical columns in a block, those exact numbers are an example implementation. Other embodiments may include more or fewer regions per block; more or fewer rows of memory holes/vertical columns per region; and more or fewer rows of vertical columns per block.

FIG. 4C also shows the memory holes/vertical columns being staggered. In other embodiments, different patterns of staggering can be used. In some embodiments, the memory holes/vertical columns are not staggered.

FIG. 4D depicts a portion of one embodiment of a three dimensional memory structure 202 showing a cross-sectional view along line AA of FIG. 4C. This cross sectional view cuts through memory holes/vertical columns (NAND strings) 428 and 430 of region 462 (see FIG. 4C).

The structure of FIG. 4D includes two drain side select layers SGD0 and SGD1; two source side select layers SGS0 and SGS1; two drain side GIDL generation transistor layers SGDT0 and SGDT1; two source side GIDL generation transistor layers SGSB0 and SGSB1; two drain side dummy word line layers DD0 and DD1; two source side dummy word line layers DS0 and DS1; dummy word line layers DU and DL that are separated by a joint; one hundred and sixty two word line layers WL0-WL161 for connecting to data memory cells; and dielectric layers DL. Other embodiments can implement more or fewer than the numbers described above for FIG. 4D. In one embodiment, SGD0 and SGD1 are connected together and SGS0 and SGS1 are connected together. In other embodiments, more or fewer SGDs (greater or lesser than two) are connected together and more or fewer SGS devices (greater or lesser than two) are connected together.

In one embodiment, erasing the memory cells is performed using gate induced drain leakage (GIDL), which includes generating charge carriers at the GIDL generation transistors such that the carriers get injected into the charge trapping layers of the NAND strings to change (reduce) respective threshold voltages Vt of the memory cells. In the embodiment of FIG. 4D, there are two GIDL generation transistors at each end of the NAND string; however, in other embodiments there are more or fewer than two GIDL generation transistors.

Embodiments that use GIDL at both sides of the NAND string may have GIDL generation transistors at both sides. Embodiments that use GIDL at only the drain side of the NAND string may have GIDL generation transistors only at the drain side. Embodiments that use GIDL at only the source side of the NAND string may have GIDL generation transistors only at the source side.

The GIDL generation transistors have an abrupt PN junction to generate the charge carriers for GIDL and, during fabrication, a phosphorous diffusion is performed at the polysilicon channel of the GIDL generation transistors. In some cases, the GIDL generation transistor with the shallowest phosphorous diffusion is the GIDL generation transistor that generates the charge carriers during erase. However, in some embodiments charge carriers can be generated by GIDL at multiple GIDL generation transistors at a particular side of the NAND string.

The memory holes/vertical columns 428, 430 are depicted protruding through the drain side select layers, source side select layers, dummy word line layers, GIDL generation transistor layers and word line layers. In one embodiment, each memory hole/vertical column comprises a vertical NAND string. Below the memory holes/vertical columns and the layers listed below is substrate 464, an insulating film 466 on the substrate, and source line SL. The NAND string of memory hole/vertical column 428 has a source end at a bottom of the stack and a drain end at a top of the stack. As in agreement with FIG. 4C, FIG. 4D show vertical memory hole/column 428 connected to bit line 442 via connector 468.

For ease of reference, drain side select layers, source side select layers, dummy word line layers, GIDL generation transistor layers and data word line layers collectively are referred to as conductive layers.

In one embodiment, the conductive layers are made from a combination of TiN and Tungsten. In other embodiments, other materials can be used to form the conductive layers, such as doped polysilicon, metal such as Tungsten, metal silicide, such as nickel silicide, tungsten silicide, aluminum silicide or the combination thereof.

In some embodiments, different conductive layers can be formed from different materials. Between conductive layers are dielectric layers DL. In one embodiment, the dielectric layers are made from SiO₂. In other embodiments, other dielectric materials can be used to form the dielectric layers.

The non-volatile memory cells are formed along memory holes/vertical columns which extend through alternating conductive and dielectric layers in the stack. In one embodiment, the memory cells are arranged in NAND strings. The word line layers WL0-W161 connect to memory cells (also called data memory cells). The dummy word line layers connect to a plurality of dummy memory cells, which do not store data. In some embodiments, the data memory cells and the dummy memory cells may have a same structure. The drain side select layers SGD0 and SGD1 are used to electrically connect and disconnect the NAND strings to and from the bit lines. The source side select layers SGS0 and SGS1 are used to electrically connect and disconnect the NAND strings to and from the source line SL.

FIG. 4D shows that the memory array is implemented as a two tier architecture, with the tiers separated by a joint area. In one embodiment, it is expensive and/or challenging to etch so many word line layers intermixed with dielectric layers. To ease this burden, a first stack of word line layers (e.g., WL0-WL80) are laid down with alternating dielectric layers, then the Joint area is laid down, and next, a second stack of word line layers (e.g., WL81-WL161) are laid down with alternating dielectric layers. The joint area is thus positioned between the first stack of word line layers and the second stack of word line layers. In one embodiment, the joint areas are made from the same materials as the word line layers. In other embodiments, there can no joint area or there can be multiple joint areas.

FIG. 4E depicts a portion of one embodiment of a three dimensional memory structure 202 showing a cross-sectional view along line BB of FIG. 4C. This cross sectional view cuts through memory holes/vertical columns (NAND strings) 416 and 470 of region 454 (see FIG. 4C). FIG. 4E shows the same alternating conductive and dielectric layers as FIG. 4D.

FIG. 4E also shows isolation region 446, which occupies a space that would have been used for a portion of the memory holes/vertical columns/NAND stings, including a space that would have been used for a portion of memory hole/vertical column 470. More specifically, a portion (e.g., half the diameter) of vertical column 470 has been removed in layers SGDT0, SGDT1, SGD0, and SGD1 to accommodate isolation region 446. Thus, while most of the vertical column 470 is cylindrical (has a circular cross section), the portion of vertical column 470 in layers SGDT0, SGDT1, SGD0, and SGD1 has a semi-circular cross section. In one embodiment, after the stack of alternating conductive and dielectric layers is formed, the stack is etched to create space for the isolation region and that space is then filled in with SiO₂. This structure allows for separate control of SGDT0, SGDT1, SGD0, and SGD1 for regions 454, 456, 458, 460, and 462 (illustrated in FIG. 4C).

FIG. 4F depicts a cross sectional view of region 472 of FIG. 4D that includes a portion of memory hole/vertical column 428. In one embodiment, the memory holes/vertical columns are round. However, in other embodiments other shapes can be used. In one embodiment, memory hole/vertical column 428 includes an inner core layer 474 that is made of a dielectric, such as SiO₂. Surrounding the inner core 474 is a polysilicon channel 476 (materials other than polysilicon can alternately be used). The channel 476 extends between and is connected with the bit line and the source line. Surrounding the channel 476 is a tunneling dielectric 478 layer, which may have an ONO structure. Surrounding the tunneling dielectric 478 layer is charge trapping layer 480, which may be formed of, for example, Silicon Nitride. It should be appreciated that the technology described herein is not limited to any particular material or structure.

FIG. 4F depicts the dielectric layers DL as well as the word line layers WL160, WL159, WL158, WL157, and WL156. Each of these word line layers includes a word line region 482 surrounded by an aluminum oxide layer 484, which is surrounded by a blocking oxide layer 486. In other embodiments, the blocking oxide layer 486 can be a vertical layer that is parallel with and adjacent to the charge trapping layer 480. The physical interaction of the word line layers with the vertical column forms the memory cells of the NAND string. Thus, in one embodiment a memory cell includes the channel 476, the tunneling dielectric 478, the charge trapping layer 480, the blocking oxide layer 486, the aluminum oxide layer 484, and the word line region 482. For example, word line layer WL160 and a portion of memory hole/vertical column 428 comprise a memory cell MC1. Word line layer WL159 and a portion of memory hole/vertical column 428 comprise a memory cell MC2. Word line layer WL158 and a portion of memory hole/vertical column 428 comprise a memory cell MC3. Word line layer WL157 and a portion of memory hole/vertical column 428 comprise a memory cell MC4. Word line layer WL156 and a portion of memory hole/vertical column 428 comprise a memory cell MC5. In other architectures, a memory cell may have a different structure; however, the memory cell would still be the storage unit.

When a memory cell is programmed, electrons are stored in a portion of the charge trapping layer 480 which is associated with (e.g., in) the memory cell. These electrons are drawn into the charge trapping layer 480 from the channel 476, through the tunneling dielectric 478, in response to an appropriate voltage on word line region 482. The threshold voltage (Vth) of a memory cell is increased in proportion to the amount of stored charge.

In one embodiment, the programming is achieved through Fowler-Nordheim tunneling of the electrons into the charge trapping layer 480. During an erase operation, the electrons return to the channel 476 or holes are injected into the charge trapping layer 480 to recombine with electrons. In one embodiment, erasing is achieved using hole injection into the charge trapping layer 480 via a physical mechanism such as GIDL, as described above.

FIG. 4G is a schematic diagram of a portion of the three dimensional memory array depicted in in FIGS. 4B-4F. FIG. 4G shows physical data word lines WL0-WL161 running across the entire block. The structure of FIG. 4G corresponds to a portion 412 in Block 2 of FIG. 4B, including bit line 436. Within the block, in one embodiment, each bit line is connected to five NAND strings, one in each region of regions 454, 456, 458, 460, 462 (illustrated in FIG. 4C).

In one embodiment, the programming is achieved through Fowler-Nordheim tunneling of the electrons into the charge trapping layer 480. During an erase operation, the electrons return to the channel 476 or holes are injected into the charge trapping layer 480 to recombine with electrons. In one embodiment, erasing is achieved using hole injection into the charge trapping layer 480 via a physical mechanism such as GIDL, as described above.

FIG. 4G is a schematic diagram of a portion of the three dimensional memory array depicted in in FIGS. 4B-4F. FIG. 4G shows physical data word lines WL0-WL161 running across the entire block. The structure of FIG. 4G corresponds to a portion 412 in Block 2 of FIG. 4B, including bit line 436. Within the block, in one embodiment, each bit line is connected to five NAND strings, one in each region of regions 454, 456, 458, 460, 462 (illustrated in FIG. 4C).

Similarly, the drain side select line/layer SGD1 is separated by isolation regions 446, 448, 450, and 452 (illustrated in FIG. 4C) to form SGD1-s0, SGD1-s1, SGD1-s2, SGD1-s3 and SGD1-s4 in order to separately connect to and independently control regions 454, 456, 458, 460, 462 (illustrated in FIG. 4C). The drain side GIDL generation transistor control line/layer SGDT0 is also separated by isolation regions 446, 448, 450 and 452 to form SGDT0-s0, SGDT0-s1, SGDT0-s2, SGDT0-s3 and SGDT0-s4 in order to separately connect to and independently control regions 454, 456, 458, 460, 462. Further, the drain side GIDL generation transistor control line/layer SGDT1 is separated by isolation regions 446, 448, 450 and 452 to form SGDT1-s0, SGDT1-s1, SGDT1-s2, SGDT1-s3 and SGDT1-s4 in order to separately connect to and independently control regions 454, 456, 458, 460, 462.

FIG. 4G only shows NAND strings connected to bit line 436. However, a full schematic of the block would show every bit line and five vertical NAND strings, which are in separate regions, connected to each bit line.

Although the example memories of FIGS. 4B-4G are three dimensional memory structures that include vertical NAND strings with charge-trapping material, other (2D and 3D) memory structures can also be used with the technology described herein.

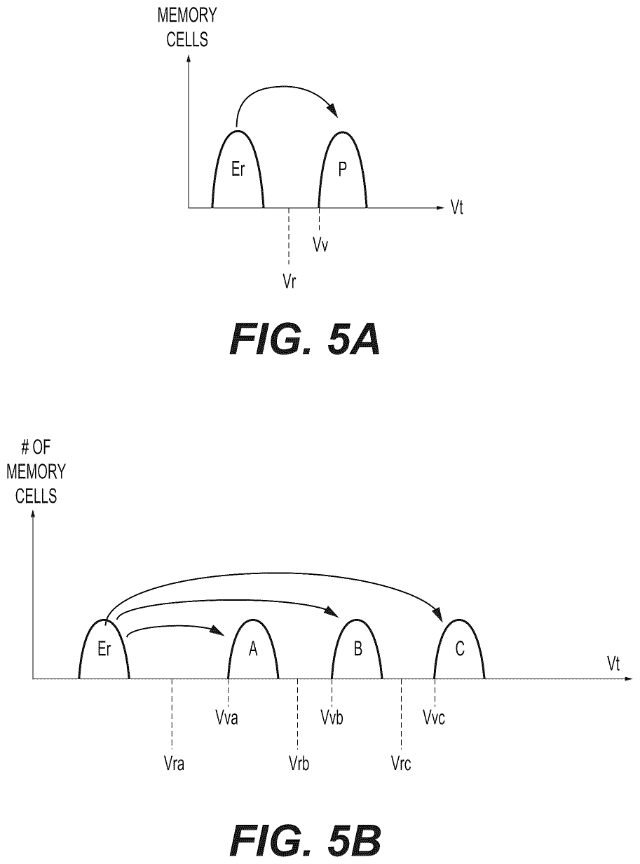

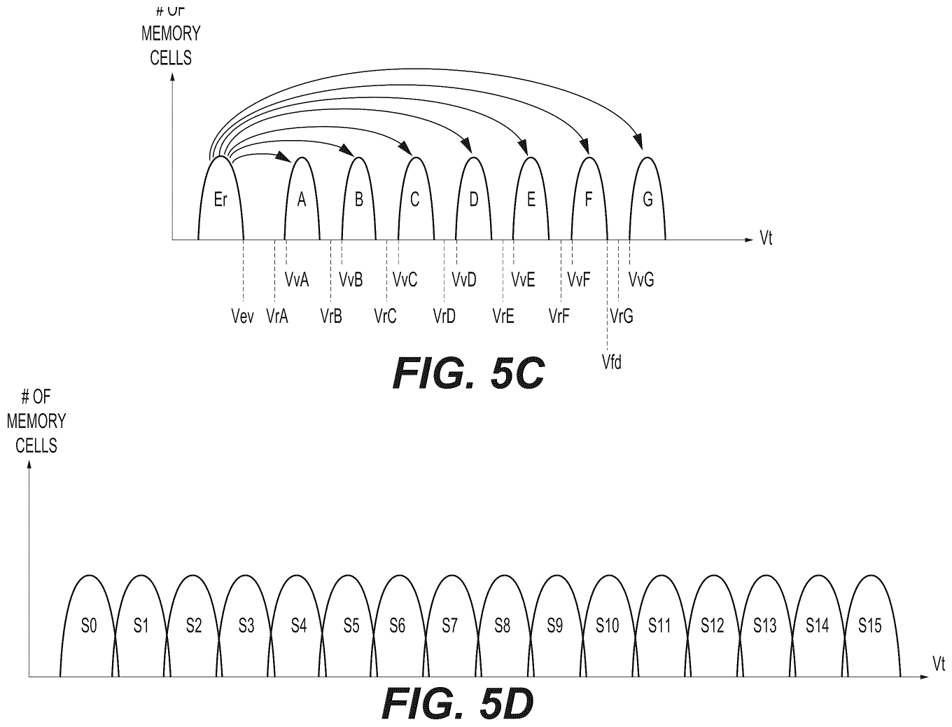

The memory systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate. FIG. 5A is a graph of number of memory cells versus threshold voltage Vt, and illustrates example threshold voltage distributions a plurality of memory cells that are programmed to one bit of data per memory cell. Such memory cells are frequently referred to as single level cells (“SLC”), and the data stored in SLC memory cells is frequently referred to as SLC data. As illustrated in FIG. 5A, there are two threshold voltage Vt distributions: Er and P. The threshold voltage Vt distribution Er corresponds to an erased data state, and the threshold voltage distribution P corresponds to a programmed data state. In one embodiment, the memory cells in the erased data state Er are associated with the bit “1,” and the memory cells in the programmed data state P are associated with the bit “0.” FIG. 5A also depicts a read reference voltage Vr. During a read operation, by testing (e.g., performing one or more sense operations) whether the threshold voltage Vt of a given memory cell is above or below the read reference voltage Vr, the system can determine if that memory cell is in the erased data state Er or is in the programmed data state P. FIG. 5A also depicts a verify reference voltage Vv. In some embodiments, when programming memory cells to data state P, the system will test whether those memory cells have a threshold voltage Vt greater than or equal to the verify voltage Vv. Programming continues until a predetermined number of memory cells have threshold voltages Vt that are above the verify voltage Vv.

FIGS. 5B-D illustrate example threshold voltage Vt distributions for memory cells that are programmed to retain multiple bits of data per memory cell. FIG. 5B illustrates a threshold voltage Vt distribution of a plurality of memory cells programmed to two bits per memory cell (MLC). In this embodiment, a first threshold voltage distribution represents the memory cells in the erased data state Er. Three threshold voltage distributions A, B and C represent the memory cells programmed to data state A, data state B, and data state C respectively. In one embodiment, the memory cells in the erased data state Er are at threshold voltages Vt, and the memory cells in the data states A, B, and C are at positive threshold voltages Vt. Each of the data states corresponds to predetermined values for the set of data bits. In one embodiment, each bit of data of the two bits of data stored in a memory cell are in different logical pages, referred to as a lower page (LP) and an upper page (UP). In other embodiments, all bits of data stored in a memory cell are in a common logical page. The specific relationship between the data programmed into the memory cell and the threshold voltage levels of the cell depends upon the data encoding scheme adopted for the cells. Table 1 provides an example encoding scheme.

TABLE 1

| | E | A | B | C |
|---|---|---|---|---|
| LP | 1 | 0 | 0 | 1 |
| UP | 1 | 1 | 0 | 0 |

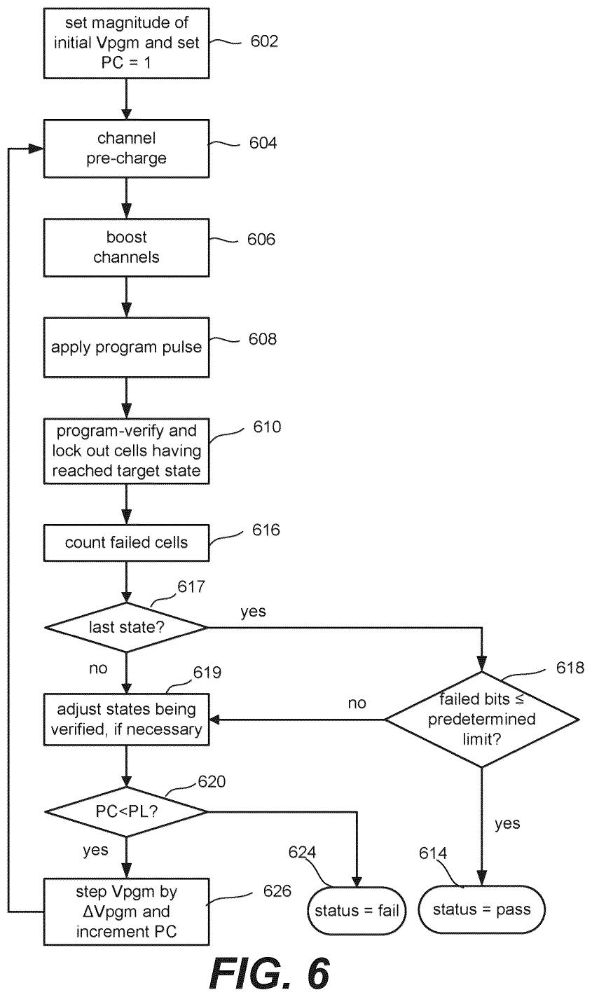

In one embodiment, known as full sequence programming, memory cells can be programmed from an erased condition directly to any of the programmed data states A, B or C using the process of FIG. 6 (discussed below). More specifically, a population of memory cells to begin programming in the erased data state Er. Then, some of the memory cells are programmed in a plurality of program loops directly to data states A, B, and/or C. For example, while some memory cells are programmed from the erased data state Er to data state A, other memory cells are being programmed from the erased data state Er to data state B, and other memory cells are programmed from the erased data state Er to data state C. The arrows of FIG. 5B represent the full sequence programming. In some embodiments, the threshold voltage Vt distributions of the programmed data states A-C can overlap with one another, and the memory controller 104 (or control die 244) can rely on error correction to identify the correct data that is stored in the memory cells. FIG. 5B also illustrates read voltages Vra, Vrb, and Vrc and verify voltages Vva, Vvb, and Vvc. The read voltages Vra, Vrb, and Vrc are used during read operations to determine which data states the memory cells are in, and the verify voltages Vva, Vvb, and Vvc are used during programming to establish when the threshold voltage Vt of a memory cell being programmed has reached its intended data state.

FIG. 5C depicts example threshold voltage Vt distributions for a plurality of memory cells that have been programmed to three bits of data per memory cells (TLC). According to this storage state, there are eight data states including an erased data state Er and seven programmed data states A-G. Each threshold voltage Vt distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage Vt of a memory erroneously shifts to its neighboring physical state, only one bit will be affected. Table 2 provides an example of an encoding scheme for embodiments in which each bit of data of the three bits of data stored in a memory cell are in different logical pages, referred to as a lower page (LP), middle page (MP) and an upper page (UP).

TABLE 2

| | Er | A | B | C | D | E | F | G |
|---|---|---|---|---|---|---|---|---|
| UP | 1 | 1 | 1 | 0 | 0 | 0 | 0 | 1 |
| MP | 1 | 1 | 0 | 0 | 1 | 1 | 0 | 0 |
| LP | 1 | 0 | 0 | 0 | 0 | 1 | 1 | 1 |

FIG. 5C shows seven read reference voltages, VrA, VrB, VrC, VrD, VrE, VrF, and VrG for use during reading operations. By testing (e.g., performing sense operations) whether the threshold voltage Vt of a given memory cell is above or below the seven read reference voltages, the system can determine what data state (i.e., Er, A, B, C, D, . . . ) a memory cell is in.

FIG. 5C also shows seven verify reference voltages, VvA, VvB, VvC, VvD, VvE, VvF, and VvG. In some embodiments, when programming memory cells to data state A, the system will test whether those memory cells have threshold voltage Vt greater than or equal to VvA; when programming memory cells to data state B, the system will test whether the memory cells have threshold voltages Vt greater than or equal to VvB, and so on for each of the programmed data states A-G. FIG. 5C also shows an erase verify voltage Vev, which is used to test whether a memory cell has been fully erased during an erase operation.

In an embodiment that utilizes full sequence programming, the memory cells can be programmed from the erased data state Er directly to any of the programmed data states A-G using the process of FIG. 6 (discussed below). For example, a population of memory cells to be programmed may first be erased so that all memory cells in the population are in erased data state Er. Then, a programming process is used to program many of the memory cells directly into data states A, B, C, D, E, F, and/or G. The arrows of FIG. 5C represent the full sequence programming. In some embodiments, the distribution curves of data states A-G can overlap one another, and the control die 244 and/or memory controller 104 can rely on error correction to identify the correct data being stored. Note that in some embodiments, rather than using full sequence programming, the system can use multi-pass programming processes known in the art.

In general, during verify operations and read operations, the selected word line is connected to a reference voltage (one example of a reference signal), a level of which is specified for each read operation (e.g., see read compare voltages/levels VrA, VrB, VrC, VrD, VrE, VrF, and VrG of FIG. 5C) or verify operation (e.g. see verify target voltages/levels VvA, VvB, VvC, VvD, VvE, VvF, and VvG of FIG. 5C) in order to determine whether a threshold voltage Vt of the selected memory cell. After applying the reference voltage to the word line, a sense node is discharged through a bit line that is coupled with the selected memory cell, and the conduction current of the memory cell is measured to determine whether the memory cell turned on (conducts current) in response to the reference voltage or is turned off (does not conduct current). If the conduction current is measured to be greater than a certain value, then it is assumed that the memory cell turned on and the reference voltage applied to the word line is greater than the threshold voltage Vt of the memory cell. If the conduction current is not measured to be greater than the certain value, then it is assumed that the memory cell did not turn on and the reference voltage applied to the word line is not greater than the threshold voltage Vt of the selected memory cell. During a read or verify process, the unselected memory cells are provided with one or more read pass voltages (also referred to as bypass voltages) at their control gates so that these memory cells will be turned on and operate as pass gates (e.g., conducting current regardless of whether they are programmed or erased).

There are many ways to measure the conduction current of a memory cell during a read or verify operation. In one example, the conduction current of a memory cell is measured by the rate it discharges or charges a dedicated capacitor in the sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. Note that the technology described herein can be used with different methods known in the art for verifying/reading. Other read and verify techniques known in the art can also be used.

FIG. 5D depicts threshold voltage Vt distributions of a plurality of memory cells that are programmed to four bits of data per memory cell (QLC). In this example, there is some overlap between the threshold voltage Vt distributions of the sixteen data states S0-S15. The overlap may occur due during use of the memory device due to factors, such as memory cells losing charge (and hence dropping in threshold voltage). Program disturb and read disturb can unintentionally increase the threshold voltage Vt of a memory cell. Over time, the locations of the threshold voltage Vt distributions may change. Such changes can increase the bit error rate (read errors), thereby increasing decoding time or even making decoding impossible. Changing the read reference voltages can help to mitigate such effects. Using ECC during the read process can also fix read errors and ambiguities. In some embodiments, the threshold voltage Vt distributions for a population of memory cells storing four bits of data per memory cell do not overlap and are separated from each other. Although not illustrated, the threshold voltage Vt distributions of FIG. 5D will include read reference voltages and verify reference voltages, as discussed above.

When using four bits per memory cell, the memory cells can be programmed using the full sequence programming discussed above or can be programmed using a multi-pass programming processes. Each threshold voltage distribution (data state) of FIG. 5D corresponds to predetermined values for the set of data bits. The specific relationship between the data programmed into the memory cell and the threshold voltage Vt levels of the cell depends upon the data encoding scheme adopted for the cells. Table 3 provides an example of an encoding scheme for embodiments in which each bit of data of the four bits of data stored in a memory cell are in different logical pages, referred to as a lower page (LP), middle page (MP), an upper page (UP) and top page (TP).

TABLE 3

| | S0 | S1 | S2 | S3 | S4 | S5 | S6 | S7 | S8 | S9 | S10 | S11 | S12 | S13 | S14 | S15 |
|---|---|---|---|---|---|---|---|---|---|---|---|---|---|---|---|---|
| TP | 1 | 1 | 1 | 1 | 1 | 0 | 0 | 0 | 0 | 0 | 1 | 1 | 0 | 0 | 0 | 1 |
| UP | 1 | 1 | 0 | 0 | 0 | 0 | 0 | 0 | 1 | 1 | 1 | 1 | 1 | 1 | 0 | 0 |
| MP | 1 | 1 | 1 | 0 | 0 | 0 | 0 | 1 | 1 | 0 | 0 | 0 | 0 | 1 | 1 | 1 |
| LP | 1 | 0 | 0 | 0 | 1 | 1 | 0 | 0 | 0 | 0 | 0 | 1 | 1 | 1 | 1 | 1 |

FIG. 6 is a flowchart describing one embodiment of a process for programming a plurality of memory cells in a selected word line. For purposes of this document, the term program and programming are synonymous with write and writing. In one example embodiment, the process of FIG. 6 is performed for memory array 202 using the one or more control circuits (e.g., the system control logic 208, the column control circuitry 216, and/or the row control circuitry 204) discussed above. In one example embodiment, the process of FIG. 6 is performed by the memory die using the one or more control circuits (e.g., the system control logic 208, the column control circuitry 216, and/or the row control circuitry 204) of control die 244 to program memory cells on memory array die 202. The process includes multiple loops, each of which includes a program phase and a verify phase. The process of FIG. 6 is performed to implement the full sequence programming, as well as other programming schemes including multi-stage programming. When implementing multi-stage programming, the process of FIG. 6 is used to implement any/each stage of the multi-stage programming process.

Typically, the program voltage applied to the control gates (via a selected word line) during a program operation is applied as a series of program voltage pulses (Vpgm pulses). Between Vpgm voltage pulses are a set of verify pulses (e.g., voltage pulses) to perform verification on the memory cells of the selected word line. In many implementations, the magnitude of the VPGM pulses is increased with each successive pulse by a predetermined step size ΔVPGM. In step 602 of FIG. 6, the programming voltage Vpgm is initialized to a starting magnitude (e.g., ˜12-16V or another suitable level) and a program counter PC maintained by state machine 262 is initialized at 1. In one embodiment, the group of memory cells selected to be programmed (referred to herein as the selected memory cells) are programmed concurrently and are all connected to the selected word line. In each program loop, there will be other memory cells that are not selected for programming (unselected memory cells) that are also connected to the selected word line, e.g., the memory cells to remain in the erased data state and the memory cells that have completed programming. The NAND strings (e.g., unselected NAND strings) that are coupled with the unselected memory cells of the selected word line have their channels boosted to an inhibit voltage to inhibit programming of the unselected memory cells. When a channel has a boosted voltage, the voltage differential between the channel and the selected word line is not large enough to cause programming in the unselected memory cell. To assist in the boosting, in step 604 the control die will pre-charge the channels of the NAND strings that include memory cells connected to the selected word line WLn that are to be inhibited from programming. In step 606, NAND strings that include memory cells connected to the selected word line that are to be inhibited from programming have their channels boosted to inhibit programming. Such NAND strings are referred to herein as “unselected NAND strings.” In one embodiment, the unselected word lines receive one or more boosting voltages (e.g., ˜7-11 volts) to perform boosting schemes. A program inhibit voltage is applied to the bit lines coupled the unselected NAND strings.

In step 608, a program voltage pulse of the programming voltage signal Vpgm is applied to the selected word line (the word line selected for programming). If a memory cell on a NAND string should be programmed, then the corresponding bit line is biased at a very low program enable voltage. In step 608, the Vpgm pulse is applied to the selected word line so that all of the selected memory cells of the selected word line are programmed concurrently while the unselected memory cells are inhibited from programming. That is, they are programmed at the same time or during overlapping times (both of which are considered concurrent). In this manner, all of the selected memory cells connected to the selected word line will concurrently have their threshold voltages Vt change, unless they are inhibited from programming.

In step 610, program-verify is performed, which includes testing whether the selected memory cells of the selected word line have successfully reached their target data state, i.e., whether their threshold voltages Vt exceed the verify voltages associated with their target data states. Memory cells that have reached their target states are locked out from further programming by the control die, i.e., become unselected memory cells. Step 610 includes performing verification of programming by sensing at one or more verify reference levels. In one embodiment, the verification process is performed by testing whether the threshold voltages Vt of the selected memory cells have reached the appropriate verify reference voltage. In step 610, a memory cell may be locked out after the memory cell has been verified (by a test of the Vt) that the memory cell has reached its target data state.

In one embodiment of step 610, a smart verify technique is used such that the system only verifies a subset of data states during a program loop (steps 604-628). For example, the first program loop includes verifying for data state A (see FIG. 5C), depending on the result of the verify operation the second program loop may perform verify for data states A and B, depending on the result of the verify operation the third program loop may perform verify for data states B and C, and so on.

In step 616, the number of memory cells that have not yet reached their respective target threshold voltage Vt distribution are counted. That is, the number of memory cells that have, so far, failed to reach their target state are counted. This counting can be done by the state machine 228, the memory controller 104, and/or another circuit. In one embodiment, there is one total count, which reflects the total number of memory cells currently being programmed that have failed the last verify step. In another embodiment, separate counts are kept for each data state.

In step 617, the system determines whether the verify operation in the latest performance of step 610 included verifying for the last data state (e.g., data state G of FIG. 5C). If so, then in step 618, it is determined whether the count from step 616 is less than or equal to a predetermined limit for the last data state. In one embodiment, the predetermined limit is the number of bits that can be corrected by an error correction codes (ECC) during a read process for the page of memory cells. If the number of failed cells is less than or equal to the predetermined limit, then the programming process can stop and a status of “PASS” is reported in step 614. In this situation, enough memory cells programmed correctly such that the few remaining memory cells that have not been completely programmed can be corrected using ECC during the read process. In some embodiments, the predetermined limit used in step 618 is below the number of bits that can be corrected by error correction codes (ECC) during a read process to allow for future/additional errors. When programming less than all of the memory cells for a page, the predetermined limit can be a portion (pro-rata or not pro-rata) of the number of bits that can be corrected by ECC during a read process for the page of memory cells. In some embodiments, the limit is not predetermined. Instead, it changes based on the number of errors already counted for the page, the number of program-erase cycles performed or other criteria.

If in step 617 it was determined that the verify operation in the latest performance of step 610 did not include verifying for the last data state or in step 618 it was determined that the number of failed memory cells is not less than the predetermined limit, then in step 619 the data states that will be verified in the next performance of step 610 (in the next program loop) is adjusted as per the smart verify scheme discussed above. In step 620, the program counter PC is checked against the program limit value (PL). Examples of program limit values include 6, 12, 16, 19, 20 and 30; however, other values can be used. If the program counter PC is not less than the program limit value PL, then the program process is considered to have failed and a status of FAIL is reported in step 624. If the program counter PC is less than the program limit value PL, then the process continues at step 626 during which time the Program Counter PC is incremented by 1 and the programming voltage signal Vpgm is stepped up to the next magnitude ΔVpgm. For example, the next pulse will have a magnitude greater than the previous pulse by a step size ΔVpgm (e.g., a step size of 0.1-1.0 volts). After step 626, the process continues at step 604 and another program pulse is applied to the selected word line (by the control die) so that another program loop (steps 604-626) of the programming process of FIG. 6 is performed.

In one embodiment, the memory cells are erased prior to programming. Erasing is the process of changing the threshold voltages Vt of one or more memory cells from a programmed data state to an erased data state. For example, changing the threshold voltage of one or more memory cells from the programmed data state P to state Er of FIG. 5A, from the programmed data states A/B/C to the erased state Er of FIG. 5B, from data states A-G to erased state Er of FIG. 5C, or from programmed states S1-S15 to state S0 of FIG. 5D.

One technique to erase the memory cells is to bias a p-well (or other types of) substrate to a high voltage to charge up a NAND channel. An erase enable voltage (e.g., a low voltage) is applied to control gates of memory cells while the NAND channel is at a high voltage to erase the memory cells. Herein, this is referred to as p-well erase.

Another technique is to generate gate induced drain leakage (“GIDL”) current to charge up the NAND string channel. An erase enable voltage is applied to control gates of the memory cells, while maintaining the NAND string channel potential to erase the memory cells. Herein, this is referred to as GIDL erase. Both p-well erase and GIDL erase may be used to lower the threshold voltages Vt of the memory cells.

In one embodiment, the GIDL current is generated by causing a drain-to-gate voltage at a GIDL generation transistor (e.g., transistors connected to SGDT0, SGDT1, . . . , SGSB0, and SGSB1). In some embodiments, a select gate (e.g., SGD or SGS) can be used as a GIDL generation transistor. A transistor drain-to-gate voltage that generates a GIDL current is referred to herein as a GIDL voltage. The GIDL current may result when the GIDL generation transistor drain voltage is significantly higher than the GIDL generation transistor control gate voltage. GIDL current is a result of carrier generation, i.e., electron-hole pair generation due to band-to-band tunneling and/or trap-assisted generation. In one embodiment, GIDL current may result in one type of carriers (also referred to a charge carriers), e.g., holes, predominantly moving into the NAND channel, thereby raising or changing the potential of the channel. The other type of carriers, e.g., electrons, are extracted from the channel, in the direction of a bit line or in the direction of a source line by an electric field. During erase, the holes may tunnel from the channel to a charge storage region of the memory cells (e.g., to charge trapping layer 480) and recombine with electrons there, to lower the threshold voltages Vt of the memory cells.

The GIDL current may be generated at either end (or both ends) of the NAND string. A first GIDL voltage may be created between two terminals of a GIDL generation transistor (e.g., connected to SGDT0, SGDT1) that is connected to or near a bit line to generate a first GIDL current. A second GIDL voltage may be created between two terminals of a GIDL generation transistor (e.g., SGSB0, SGSB1) that is connected to or near a source line to generate a second GIDL current. Erasing based on GIDL current at only one end of the NAND string is referred to as a one-sided GIDL erase. Erasing based on GIDL current at both ends of the NAND string is referred to as a two-sided GIDL erase. The technology described herein can be used with one-sided GIDL erase and two-sided GIDL erase.

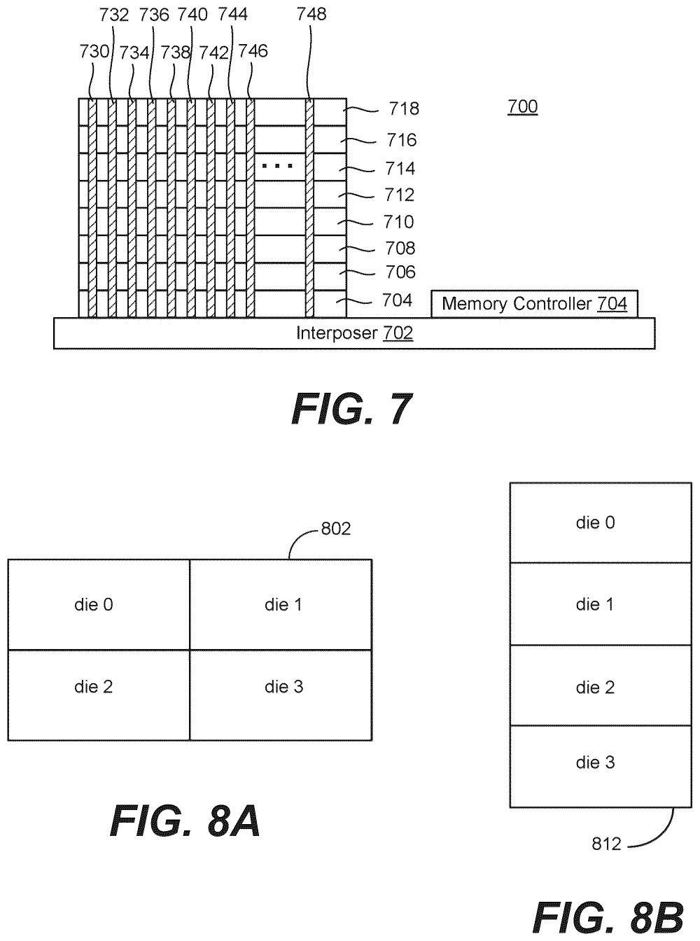

The non-volatile memory structure described above can be used to implement a memory system that is capable of performing a high bandwidth read process. FIG. 7 depicts one embodiment of a non-volatile memory system 700 capable of performing a high bandwidth read process. Non-volatile memory system 700 includes a stack of memory dies. The stack of memory dies comprises multiple layers; for example, FIG. 7 depicts eight layers: 704, 706, 708, 710, 712, 714, 716 and 718. In other embodiments, more or fewer than eight layers can be included. Each layer comprises multiple memory die. Below the eight layers 704-718 is interposer 702. Next to the stack, and depicted on top of interposer 702, is a memory controller 704. In other embodiments, the memory controller 704 can be underneath the interposer 702, off interposer 702, or in a different location. In one embodiment, memory controller 704 implements the structure of memory controller 104 of FIG. 1, while in other embodiments different architectures can be used for the memory controller 704.

The stack of memory dies comprising the eight layers 704-718 includes a plurality of TSVs. FIG. 7 depicts TSVs 730, 732, 734, 736, 738, 740, 742, 744, 746, . . . 748. In one embodiment, each memory die includes its own separate set of TSVs that are used to communicate with the memory controller 704 (via the interposer 702), and each memory die's separate set of TSVs run parallel to other memory dies' separate sets of TSVs to form parallel paths (separate parallel TSV's) to/from the memory controller 704. The TSVs can be located in any suitable location within the stack.

The interposer 702 is a component used to facilitate connections between different components or technologies that might not naturally interface with each other due to differences in form factor, electrical specifications, or other factors, i.e., the interposer 102 is an electrical interface routing between multiple connections. In the exemplary embodiment of FIG. 7, the interposer 702 connects to all of the TSVs 730-748 of each of the memory die of the eight layers 704-718 and to the memory controller 704 for purposes of routing the electrical signals between the TSVs 730-748 of each of the memory dies of the eight layers 704-718 and the memory controller 704. In this manner, the memory controller 704 can perform a high bandwidth read process for data stored in the stack across all or multiple of the memory dies of layers 704-718.

FIG. 8A is a block diagram of one layer 802 of the plurality of layers 704-718 depicted in FIG. 7. The exemplary layer 802 can be used to implement any layer of or all layers of layers 704-718. The layer 802 includes four memory dies, which are labeled as die 0, die 1, die 2, and die 3. Each of those memory dies (die 0, die 1, die 2 and die 3) can be based on the structure of FIG. 2A, the structure of FIG. 2B or a different structure for a non-volatile memory die. As will be discussed in more detail below, each memory die comprises multiple planes (arrays), and groups of planes form banks. Each memory die also has multiple I/O circuits such that there is one I/O circuit per bank, and the separate parallel TSV's (e.g., 730-748 of FIG. 7) comprise separate parallel TSV's for each I/O circuit of each memory die. In some embodiments, each I/O circuit can be associated with and in communication with multiple TSVs, e.g., four or eight TSVs per I/O circuit.

FIG. 8B is a block diagram of another exemplary embodiment of one layer of layers 704-718 of FIG. 7. The layer 812 of FIG. 8B can be used to implement any layer of or all layers of layers 704-718. The layer 812 includes four memory dies: die 0, die 1, die 2 and die 3. Each of those memory dies (die 0, die 1, die 2 and die 3) can be based on the structure of FIG. 2A, the structure of FIG. 2B or a different structure for a non-volatile memory die.

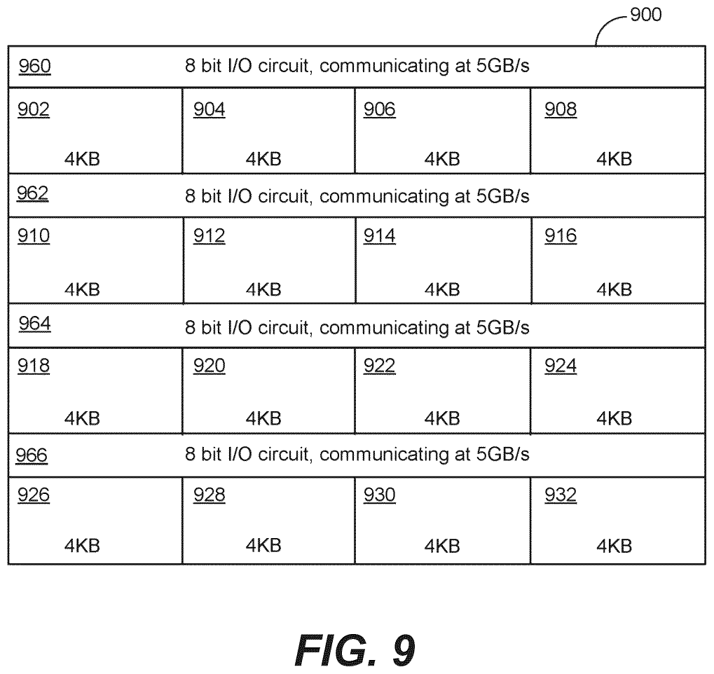

FIG. 9 is a block diagram depicting one embodiment of a partial floorplan for a memory die 900 (i.e. looking down at the memory die). In one embodiment, the memory die 900 can implement the structure of FIG. 2A, the structure of FIG. 2B or a different structure for a non-volatile memory die. The memory die 900 is an example of a memory die that can be used on each of layers 704-718 depicted in FIG. 7. That is, the memory die 900 can be used to implement memory die 0, memory die 1, memory die 2 and memory die 3 of FIGS. 8A and 8B for any or all of layers 704-718. The memory die 900 includes sixteen planes: 902, 904, 906, 908, 910, 912, 914, 916, 918, 920, 922, 924, 926, 928, 930, and 932. Each plane 902-932 is divided into pages of 4K Bytes. The planes 902-932 are grouped into banks, and the memory die 900 includes one I/O circuit per bank. In one embodiment, there are four banks for memory die 900. The first bank comprises planes 902, 904, 906 and 908 and is connected to (and uses) I/O circuit 960. That means that data to programmed into or read from planes 902, 904, 906 and 908 is communicated between the memory die 900 and the memory controller 704 via the I/O circuit 960. The second bank comprises planes 910, 912, 914, and 916 and is connected to (and uses) I/O circuit 962. That means that data to programmed into or read from planes 910, 912, 914, and 916 is communicated between the memory die 900 and the memory controller 704 via the I/O circuit 962. The third bank comprises planes 918, 920, 922, and 924, and is connected to (and uses) I/O circuit 964. That means that data to programmed into or read from planes 918, 920, 922, and 924 is communicated between the memory die 900 and the memory controller 704 via the I/O circuit 964. The fourth bank comprises planes 926, 928, 930, and 932, and is connected to (and uses) I/O circuit 966. That means that data to programmed into or read from planes 926, 928, 930, and 932 is communicated between the memory die 900 and the memory controller 704 via the I/O circuit 966.

The I/O circuits 960, 962, 964 and 966 each implement a separate eight bit data bus and are able to communicate at 5 Giga Bytes (“GB”) per second. The eight bit data bus is implemented as eight TSVs (see e.g., TSVs 730-748 of FIG. 7). Since there are four I/O circuits in the memory die 900, then the memory die 900 needs thirty two TSVs. In one embodiment, the I/O circuits 960, 962, 964, and 966 are part of the interface 234 and I/O circuits of FIG. 2A or 2B. In one embodiment, the I/O circuits 960, 962, 964, and 966 further comprise input and output drivers (large out drivers with many stages to enable the I/O driving few pF load) and clocking to track the data.

In one embodiment, the memory die 900 can sense data in 3.2 us and 64 KB can be sensed at the same time (4 KB page×16 planes). Therefore, the memory die 900 can sense at a bandwidth of 21 GB per second. Since the four I/O circuits of memory die 900 each transmit eight bits at 5 GB per second, the memory die 900 can transfer 20 GB of sensed data per second, which is slightly slower than the sensing speed of 21 GB per second. Since there are four memory die on a layer (e.g., layer 802 of FIG. 8A or FIG. 8B), each layer can transmit 80 GB per second. Since there are eight layers (see layers 704-718 of FIG. 7), the memory system of FIG. 7 can transmit 640 GB per second when implementing the memory die 900.

Looking back at FIG. 7, to implement four memory dies 900 on a level requires 32 TSVs for each of the four memory dies, for a total of 128 TSVs for each level. Since there are memory dies on eight layers (e.g., layers 704-718) then 1,024 TSVs are needed (32 TSVs per memory die×32 memory die). These 1,024 TSVs are not connected to each other (e.g., no memory die's I/O is connected to another memory die's I/O). Rather, the 1,024 TSVs are in parallel to each other and all connect to the memory controller 704 via the interposer 702. In this manner, a read process can be performed that delivers 640 GB of data per second to the memory controller 704.

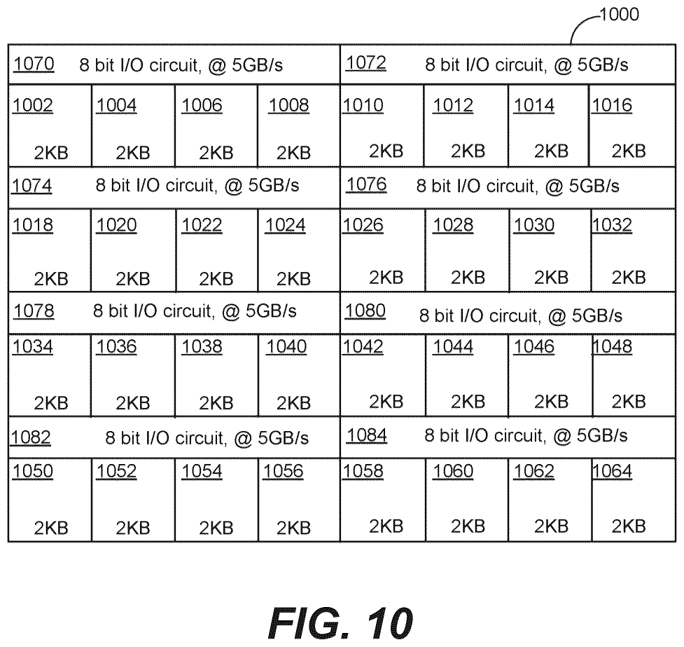

FIG. 10 is a block diagram depicting another embodiment of a partial floorplan for a memory die 1000 (i.e. looking down at the memory die). In one embodiment, the memory die 1000 can implement the structure of FIG. 2A, the structure of FIG. 2B or a different structure for a non-volatile memory die. The memory die 1000 is an example of a memory die that can be used on each of layers 704-718 depicted in FIG. 7. That is, the memory die 1000 can be used to implement die 0, die 1, die 2 and die 3 of FIGS. 8A and 8B for any or all of layers 704-718 of FIG. 7. The memory die 1000 includes thirty two planes: 1002, 1004, 1006, 1008, 1010, 1012, 1014, 1016, 1018, 1020, 1022, 1024, 1026, 1028, 1030, 1032, 1034, 1036, 1038, 1040, 1042, 1044, 1046, 1048, 1050, 1052, 1054, 1056, 1058, 1060, 1062, and 1064. Each plane is divided into pages of 2K Bytes.

The planes are grouped into banks, and the memory die 1000 includes one I/O circuit per bank. In one embodiment, there are eight banks for the memory die 1000. The first bank comprises planes 1002-1008 and is connected to (and uses) I/O circuit 1070. That means that data to programmed into or read from planes 1002-1008 is communicated between the memory die 1000 and the memory controller 704 via the I/O circuit 1070. The second bank comprises planes 1010-1016 and is connected to (and uses) I/O circuit 1074. That means that data to programmed into or read from planes 1010-1016 is communicated between the memory die 1000 and the memory controller 704 via the I/O circuit 1072. The third bank comprises planes 1018-1024 and is connected to (and uses) I/O circuit 1074. That means that data to programmed into or read from planes 1018-1024 is communicated between the memory die 1000 and the memory controller 704 via the I/O circuit 1074. The fourth bank comprises planes 1026-1032 and is connected to (and uses) I/O circuit 1076. That means that data to programmed into or read from planes 1026-1032 is communicated between the memory die 1000 and the memory controller 704 via the I/O circuit 1076. The fifth bank comprises planes 1034-1040 and is connected to (and uses) I/O circuit 1078. That means that data to programmed into or read from planes 1034-1040 is communicated between the memory die 1000 and the memory controller 704 via the I/O circuit 1078. The sixth bank comprises planes 1042-1048 and is connected to (and uses) I/O circuit 1080. That means that data to programmed into or read from planes 1042-1048 is communicated between the memory die 1000 and the memory controller 704 via the I/O circuit 1080. The seventh bank comprises planes 1050-1056 and is connected to (and uses) I/O circuit 1082. That means that data to programmed into or read from planes 1050-1056 is communicated between the memory die 1000 and the memory controller 704 via the I/O circuit 1082. The eighth bank comprises planes 1058-1064 and is connected to (and uses) I/O circuit 1084. That means that data to programmed into or read from planes 1058-1064 is communicated between the memory die 100 and the memory controller 704 via the I/O circuit 1084.

The I/O circuits 1070, 1072, 1074, 1076, 1078, 1080, 1082, and 1084 each implement a separate eight bit data bus and are able to communicate at 5 GB per second. The eight bit data bus is implemented as eight TSVs (see e.g., TSVs 730-748 of FIG. 7). Since there are eight I/O circuits in memory die 1000, then memory die 1000 needs sixty four TSVs for transmitting sixty four bits. In one embodiment, the I/O circuits 1070, 1072, 1074, 1076, 1078, 1080, 1082, and 1084 are part of the interface 234 and I/O circuits of FIG. 2A or 2B. In one embodiment, the I/O circuits 1070, 1072, 1074, 1076, 1078, 1080, 1082 and 1084 further comprise input and output drivers (large output drivers with many stages to enable the I/O driving few pF load) and clocking to track the data.

In one embodiment, the memory die 1000 can sense data in 1.6 us and 64 KB can be sensed at the same time (2 KB page×32 planes). The sensing time is shorter for the memory die 1000 as compared to the memory die 900 (depicted in FIG. 9) due to the smaller page size resulting in shorter word lines and, thus, smaller RC delays. Therefore, the memory die 1000 can sense at 40 GB per second. Since the eight I/O circuits of memory die 1000 each transmit eight bits at 5 GB per second, the memory die 900 can transfer 40 GB of sensed data per second. Since there are four memory die on a layer (e.g., layer 802 of FIG. 8A or FIG. 8B), each layer can transmit 160 GB per second. Since there are eight layers (see layers 704-718 of FIG. 7), the memory system of FIG. 7 can transmit 1,280 GB per second when implementing the memory die 1000. Thus, the embodiment of FIG. 10 has twice the bandwidth of the embodiment of FIG. 9.

To implement four memory dies 1000 on a level requires 64 TSVs for each of the four memory dies, for a total of 256 TSVs (for 256 bits of data) for each level. Since there are memory dies on eight layers (e.g., layers 704-718) then 2,048 TSVs are needed (64 TSVs per memory die×32 memory die). These 2048 TSVs are not connected to each other (e.g., no memory die's I/O is connected to another memory die's I/O). Rather the TSVs are in parallel to each other and all connect to the memory controller 704 via the interposer 702. In this manner, a read process can be performed that delivers 1,280 GB of data per second to the memory controller 704.

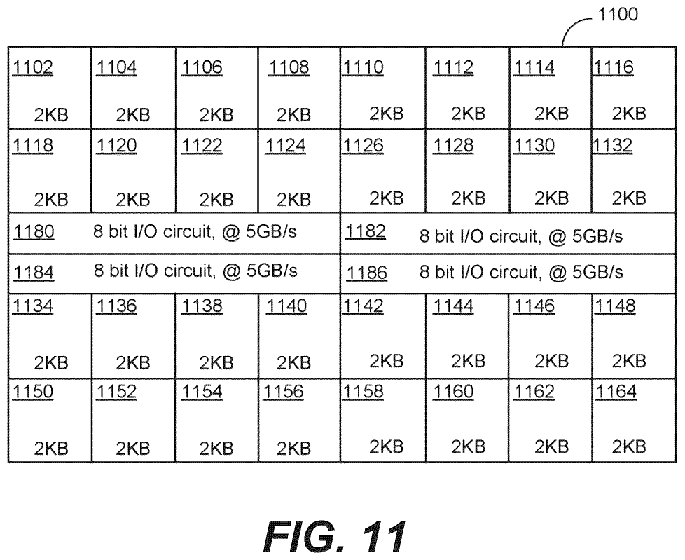

FIG. 11 is a block diagram depicting of a partial floorplan for another embodiment of a memory die 1100 (i.e. looking down at the memory die). In one embodiment, memory die 1100 can implement the structure of FIG. 2A, the structure of FIG. 2B or a different structure for a non-volatile memory die. The memory die 1100 is an example of a memory die that can be used on each of layers 704-718 depicted in FIG. 7. That is, the memory die 1100 can be used to implement die 0, die 1, die 2 and die 3 of FIGS. 8A and 8B for any or all of layers 704-718. The memory die 1100 includes thirty two planes: 1102, 1104, 1106, 1108, 1110, 1112, 1114, 1116, 1118, 1120, 1122, 1124, 1126, 1128, 1130, 1132, 1134, 1136, 1138, 1140, 1142, 1144, 1146, 1148, 1150, 1152, 1154, 1156, 1158, 1160, 1162, and 1164. Each plane is divided into pages of 2K Bytes. In one embodiment, a page is the unit of reading and/or programming, while a block is the unit of erase.

The planes are grouped into banks, and the memory die 1100 includes one I/O circuit per bank. In one embodiment, there are four banks for memory die 1100. The first bank comprises planes 1102, 1104, 1106, 1108, 1118, 1120, 1122, and 1124 and is connected to (and uses) I/O circuit 1080. The second bank comprises planes 1110, 1112, 1114, 1116, 1126, 1128, 1130, and 1132 and is connected to (and uses) I/O circuit 1182. The third bank comprises planes 1134, 1136, 1138, 1140, 1150, 1152, 1154, and 1156 and is connected to (and uses) I/O circuit 1184. The fourth bank comprises planes 1142, 1144, 1146, 1148, 1158, 1160, 1162, and 1164 and is connected to (and uses) I/O circuit 1186.

The I/O circuits 1080, 1082, 1084, and 1086 each implement a separate eight bit data bus and are able to communicate at 5 GB per second. The eight bit data bus is implemented as eight TSVs (see e.g., TSVs 730-748 depicted in FIG. 7). Since there are four I/O circuits in memory die 1100, then the memory die 1100 needs thirty two TSVs for transmitting thirty two bits. Note that in the embodiments of FIGS. 9 and 10, the I/O circuits are dispersed in the memory die adjacent respective banks, while in the embodiment of FIG. 11, the I/O circuits are in the middle of the memory die 1100.

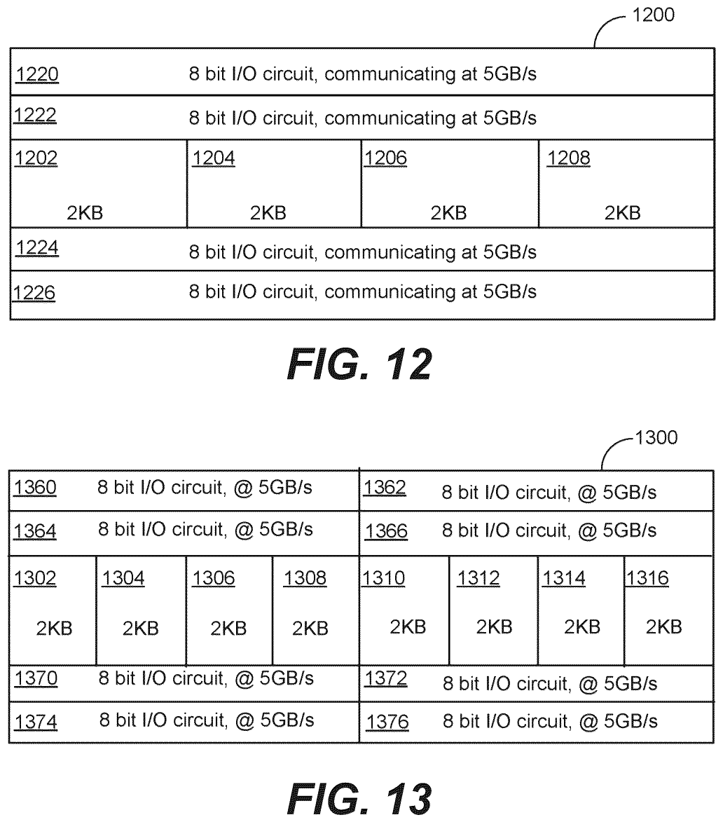

FIG. 12 is a block diagram depicting a partial floorplan for another exemplary embodiment of a memory die 1200 (i.e. looking down at the memory die). In one embodiment, the memory die 1200 can implement the structure of FIG. 2A, the structure of FIG. 2B or a different structure for a non-volatile memory die. The memory die 1200 is an example of a memory die that can be used on each of layers 704-718 depicted in FIG. 7. That is, the memory die 1200 can be used to implement die 0, die 1, die 2 and die 3 of FIGS. 8A and 8B for any or all of layers 704-718. The memory die 1200 includes four planes: 1202, 1204, 1206, and 1208, and each plane is divided into pages of 2K Bytes. In the embodiment of FIG. 12, each plane has its own dedicated I/O circuit. For example, plane 1202 is connected to I/O circuit 1220, plane 1204 is connected to I/O circuit 1222, plane 1206 is connected to I/O circuit 1206, and plane 1208 is connected to I/O circuit 1126. The planes are in the middle of the memory die 1200, and the I/O circuits are on the outer edges of the memory die 1200. The I/O circuits 1220, 1222, 1224, and 1226 each implement a separate eight bit data bus and are able to communicate at 5 GB per second. The eight bit data bus is implemented as eight TSVs (see e.g., TSVs 730-748 in FIG. 7). Since there are four I/O circuits in the memory die 1200, then the memory die 1200 needs thirty two TSVs for transmitting thirty two bits. A system with four memory die on a level and eight layers would include thirty memory die each using thirty two TSV for a total of 1,024 TSVs in the stack.

FIG. 13 is a block diagram depicting another embodiment of a partial floorplan for a memory die 1300 (i.e. looking down at the memory die). In one embodiment, the memory die 1300 can implement the structure of FIG. 2A, the structure of FIG. 2B or a different structure for a non-volatile memory die. The memory die 1300 is an example of a memory die that can be used on each of layers 704-718 depicted in FIG. 7. That is, the memory die 1300 can be used to implement die 0, die 1, die 2 and die 3 of FIGS. 8A and 8B for any or all of layers 704-718. The memory die 1200 includes eight planes: 1302, 1304, 1306, 1308, 1310, 1312, 1314, and 1316, and each plane is divided into pages of 2K Bytes. In the embodiment of FIG. 13, each plane has its own dedicated I/O circuit. For example, plane 1302 is connected to I/O circuit 1360, plane 1304 is connected to I/O circuit 1364, plane 1306 is connected to I/O circuit 1370, plane 1308 is connected to I/O circuit 1374, plane 1310 is connected to I/O circuit 1362, plane 1312 is connected to I/O circuit 1366, plane 1314 is connected to I/O circuit 1372, and plane 1316 is connected to I/O circuit 1376. The planes are in the middle of the die and the I/O circuits are on the outer edges of the die. I/O circuits 1360, 1362, 1364, 1366, 1370, 1372, 1374 and 1376 each implement a separate eight bit data bus and are able to communicate at 5 GB per second. The eight bit data bus is implemented as eight TSVs (see e.g., TSVs 730-748 in FIG. 7). Since there are eight I/O circuits in memory die 1300, then the memory die 1300 needs sixty four TSVs for transmitting sixty four bits. A system with four memory die on a level and eight layers would include thirty memory die each using sixty four TSVs for a total of 2,048 TSVs in the stack. The embodiment of FIG. 13 results in the same bandwidth and number of TSVs as the embodiment of FIG. 10.

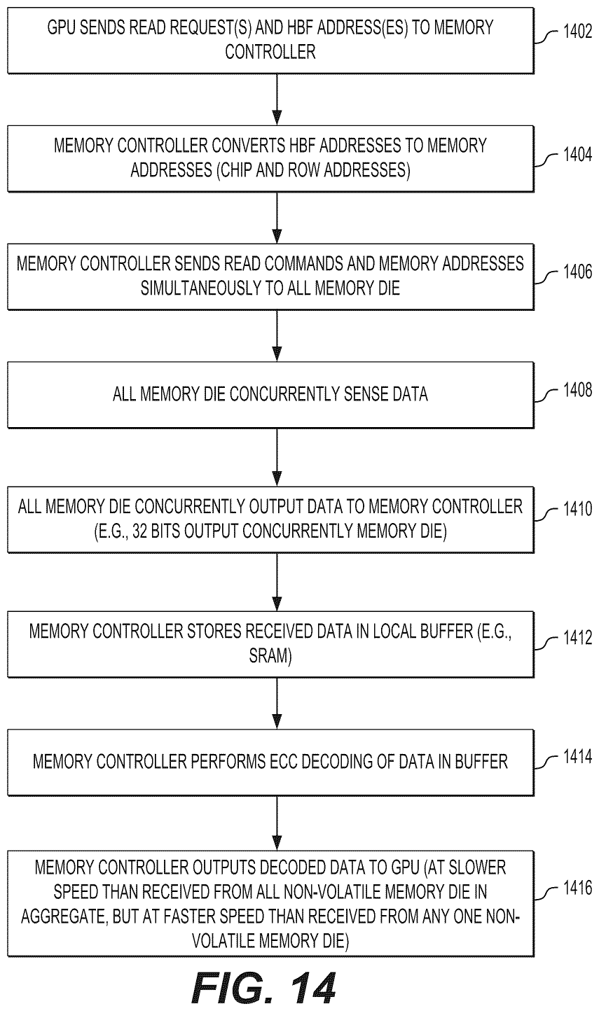

FIG. 14 is a flow chart describing one embodiment of a process for performing a high bandwidth read operation. The process of FIG. 14 can be performed with the structure of FIG. 7, implementing any of the embodiments of FIGS. 9-13. In one embodiment, each of the TSVs discussed above can be used for transmitting commands, addresses, and data between the memory die and the memory controller 704. In other embodiments, each of the TSVs discussed above are used for transmitting data only and additional TSV's are used to transmit addresses and commands. In some embodiments, addresses and commands are transmitted on different signals and in other embodiments addresses and command are combined.

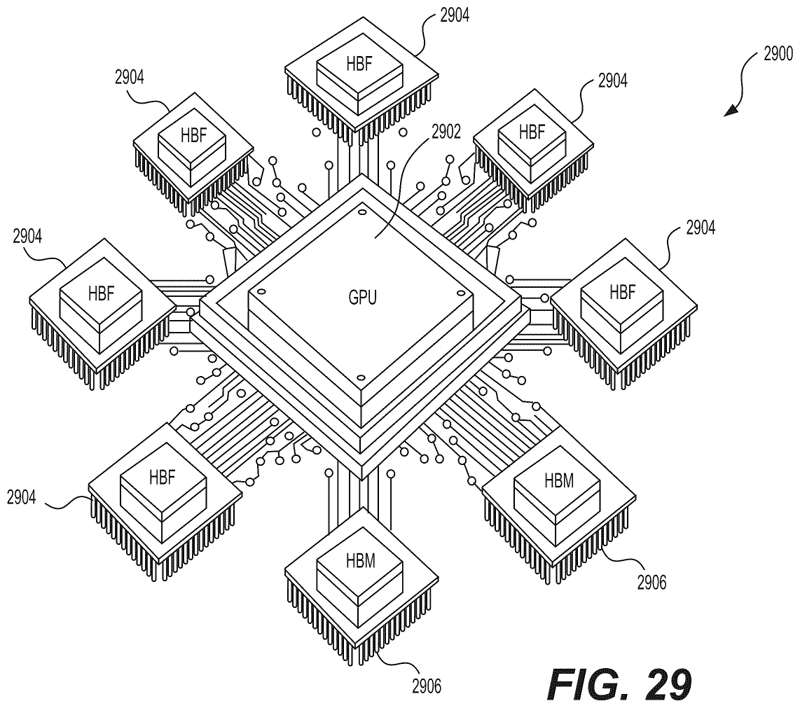

One example use case is to deploy the non-volatile memory to store a trained model for an inference engine as part of an artificial intelligence application. FIG. 29 illustrates an example embodiment of a computing system 2900 constructed according to aspects of the present disclosure and that is optimized for processing large language models in artificial intelligence applications. The computing system 2900 includes a single graphics processor unit (GPU) 2902 (or a similar processor unit), six HBF packages 2904, and two HBM packages 2906 (for example, DRAM), which are all in electrical communication with the single GPU 2902. Such a computing system 2900 may be particularly adapted for use in storing data pertaining to a large language model (LLM) because once the model data have been stored in the HBF packages 2904, the model data are not updated or changed very often. The LLM model data may include a plurality of weight matrices. Thus, for a machine learning inferencing application, the HBF packages 2904 can be considered write a few times, read many times memory. In some embodiments, the computing system 2900 can include more or fewer than eight HBF packages 2904. For example, in another embodiment, the computing system includes five HBF packages that are in electrical communication with a single GPU.

In an exemplary embodiment, each of the HBF packages 2904 includes eight memory dies, each of which includes thirty-two planes that can be independently and simultaneously be operated on. In some embodiments, the number of dies in each HBF packages and the number of planes per die can vary from these figures. Each of these HBF packages 2904 is may include one or more memory devices consistent with the embodiments described herein.

Typically, the trained model is programmed into the memory once and then read many times. To support the input needs of the inference engine, the process of reading the model must be performed at a high bandwidth. Typically, DRAM is used as a High Bandwidth Memory (“HBM”) to store a trained model. However, non-volatile memory, such as the HBF packages 2904, can be less expensive then DRAM. Therefore, the process of FIG. 14 uses the non-volatile memory of FIG. 7 as the memory to store a trained LLM (or other data). In this example use case, host is the GPU 2902 (illustrated in FIG. 29) operating as an inference engine in an artificial intelligence system. The GPU 2902 needs to read portions of the trained model from the HBF (in this case the non-volatile memory of FIG. 7).

In step 1402, the GPU sends read request(s) and HBF address(es) to the memory controller 704 in order to obtain portions of a trained model. In step 1404, the memory controller 704 converts the HBF addresses to non-volatile memory addresses (chip addresses and row addresses). The chip addresses indicate which memory die is being read. The row address indicates the page on the addressed memory die. In step 1406, the memory controller 704 sends read commands and page addresses (includes block address) simultaneously to all memory die in the stack depicted in FIG. 7. For example, read commands and page addresses are concurrently sent all thirty two memory die of the eight layers depicted in FIG. 7. Other embodiments may include more or fewer than thirty two memory die. In step 1408, all of the memory die that received read commands and addresses concurrently sense data. In step 1410, all of the memory die that sensed data concurrently output data to the memory controller 704 (e.g., 32 bits output concurrently per non-volatile memory die using the TSV's discussed above). In step 1412, the memory controller 704 stores the received data in a local buffer (e.g., static random access memory “SRAM”). There can be one buffer for data received from all memory die, or a separate buffer in the memory controller 704 for each memory die. In step 1414, the memory controller 704 performs ECC decoding of data stored in the local buffer. In another embodiment, the decoded data is moved to an output buffer rather than remaining in the local buffer where the received data was initially stored. In step 1416, the memory controller 702 outputs the decoded data to GPU (e.g., in one embodiment, at slower speed than received from all non-volatile memory die in aggregate, but at faster speed than received from any one non-volatile memory die). In one example, the data is received at the memory controller 704 at 640 GB per second or 1,280 GB per second, and the data is output to the GPU at 620 GB per second or 640 GB per second. These numbers are examples and other speeds can also be implemented. For example, data can be transmitted from the memory dies to the memory controller 704 at faster speeds than 1,280 GB per second (e.g., 2,048 GB/s if the seed on each line is increased or more lines/TSVs are used). In one example, the data is received at the memory controller 704 as 1,024 bits in parallel or 2,048 bits in parallel, and the data is output to the GPU as 64 bits in parallel.

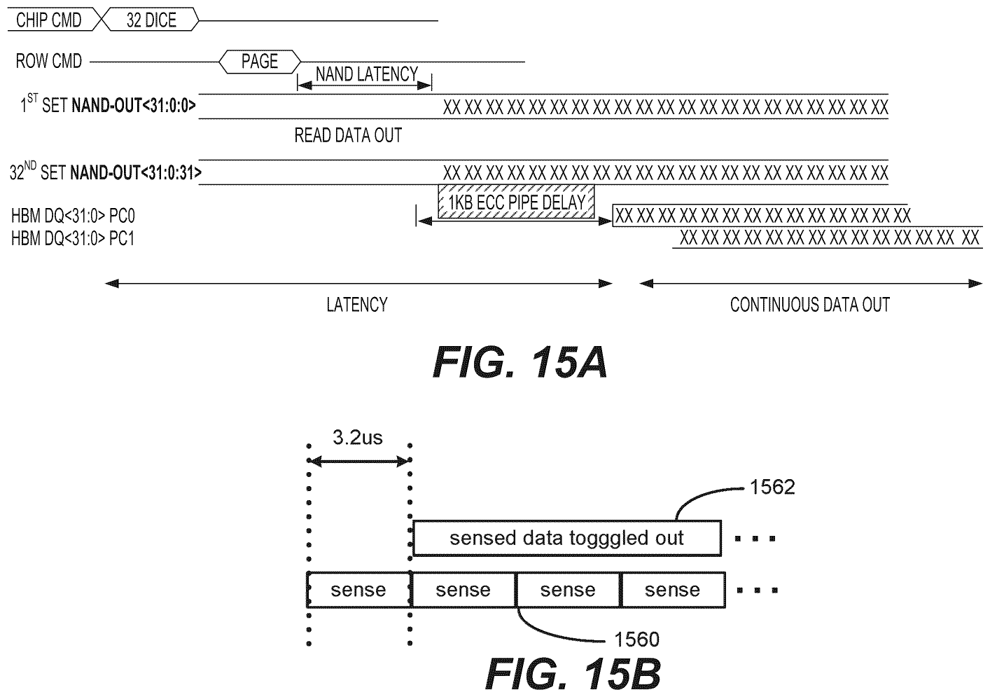

FIG. 15A is a system level timing diagram for a high bandwidth read process (e.g., the process of FIG. 14). In one embodiment, there is a separate Chip CMD signal for each memory die (from the memory controller 704 to each memory die) that transmits a command to the respective memory die. For example, the Chip CMD signal can transmit the read command of step 1406. In one embodiment, there is a separate Row CMD signal for each memory die (from the memory controller 704 to each memory die) that transmits an address to each memory die. For example, the Row CMD can transmit the block and page address of step 1406.

FIG. 15A shows the Chip CMD signal transmitting the read command simultaneously to all memory die (e.g., all 32 memory die) followed by Row CMD signal transmitting page addresses to all memory die (step 1406). After the page addresses are received, there is a latency (NAND latency) for the memory die to perform the sensing (step 1408), after which data is toggled out of the memory die to the memory controller 704 via the TSVs discussed above (labeled in FIG. 15A as 1^{st} Set NAND-OUT <31:0:0> . . . 32^{nd} Set NAND-OUT <31:0:31> (step 1410). After the data is received by the memory controller 704, there is an ECC pipe delay (e.g., ECC performed 1 KB at a time for each memory die) while the memory controller 704 performs the ECC decoding (step 1414). Once the first set of data has been decoded, it is output to the GPU (step 1416) on two 32 bit data buses HBM DQ<31:0> PC0 and HBM DQ<31:0> PC1.

In many cases, the GPU is likely to send many read requests for a large amount of data in step 1402; therefore, steps 1406-1416 will be repeated many times. However, the latencies depicted in FIG. 15A are only experienced at the first read request of a series of read requests because once the data starts being reported to the GPU the latencies for sensing and ECC are occurring concurrently with transmitting data so there is no additional latency in data reported out to the GPU (as FIG. 15A depicts “Continuous data out”).

FIG. 15B is a timing diagram for a high bandwidth read process at the memory die level. The read process at the memory die level comprises two steps: (1) sensing data and storing that data in local latches at the sense amplifier (e.g., latches are part of column control circuitry 216 of FIGS. 2A and 2B), and (2) transmitting the sensed data from the local latches to the memory controller 704. The bottom row 1560 of FIG. 15B shows the timing of the first step (sensing) and the top row 1562 shows the timing of the second step (transmitting). As mentioned above, in the embodiment of FIG. 9, sensing data takes 3.2 us. After the first sensing (the first 3.2 us) then the transmitting begins and the sensed data is toggled out to the memory controller 704. In effect, the memory die is a pipeline that senses and transmits so that after the 3.2 us latency, there is no longer a latency and data is continuously pumped out to the memory controller 704.

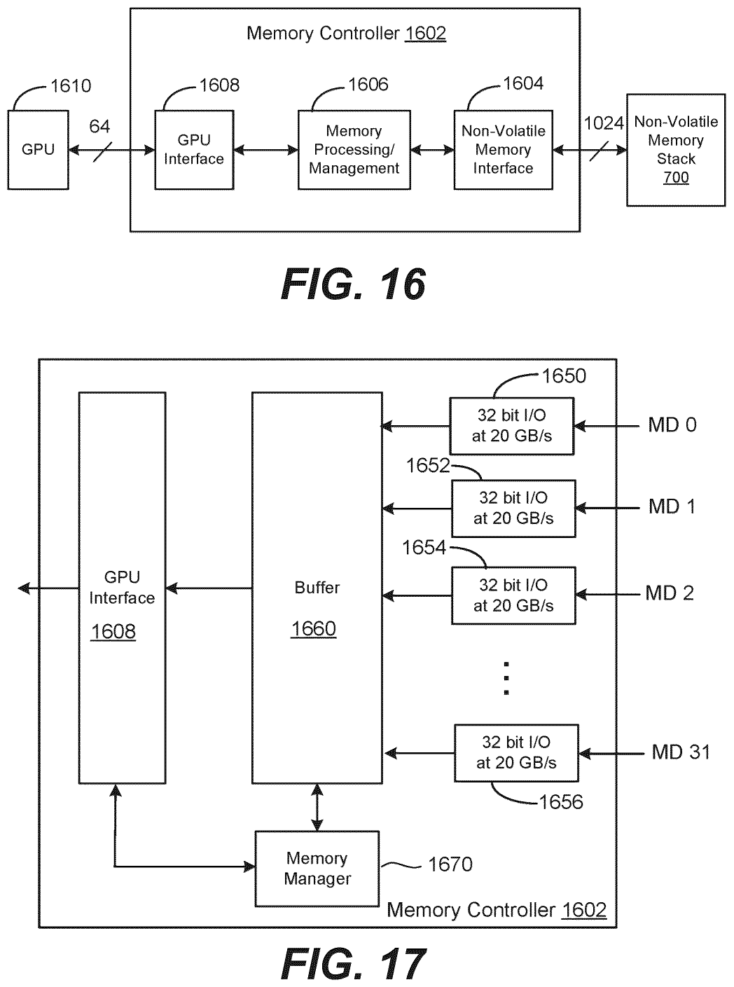

FIG. 16 is a block diagram of a memory controller 1602 and represents one example memory controller architecture (or, at least, part of the architecture). The structure of FIG. 16 is one example implementation of memory controller 104 of FIG. 1 and memory controller 704 of FIG. 7. In one embodiment, the memory controller 1602 receives 1,024 bits in parallel (or 2,048 bits in parallel) from the stack of memory die 700 (see FIG. 7) during a read process and outputs to the host (e.g., GPU 1610) 64 bits in parallel. In some embodiments, the transmission speed is faster for the output from the memory controller 1602 to GPU 1610 then the input from stack of memory die 700 to the memory controller 1602. The 1,024 bits received in parallel by the memory controller 1602 from the stack of memory die 700 during a read process is received at non-volatile memory interface 1604 (i.e., the memory interface 118 of FIG. 1), which provides an electrical interface for communication with the memory die. The data received at non-volatile memory interface 1604 is provided to the memory processing/management circuit(s) 1606, which performs ECC decoding, buffering and other operations. In one embodiment, there is a separate buffer for each memory die. In one embodiment, there is a set of buffers (e.g., 64 KB each or bigger) for receiving the data (e.g., one buffer per memory die), a set of buffers (e.g., 1 KB each or bigger) for ECC processing (e.g., one buffer per memory die) and a set of buffers (e.g., 64 KB each or bigger) for post-ECC data waiting to be reported to GPU 1610 (e.g., one buffer per memory die). The decoded data is provided to GPU interface 1608 for reporting to GPU 1610. GPU Interface 1608 is an electrical circuit for communicating with GPU 1610.

FIG. 17 is a block diagram depicting data flow at the memory controller 1602 during a high bandwidth read process. FIG. 17 shows data received from thirty two memory die (MD 0, MD 1, MD 2, . . . MD 31) at separate interface circuits for each memory die 1650, 1652, 1654, . . . 1656, which together comprise non-volatile memory interface 1604. Data from each memory die is received as 32 bits in parallel at 20 GB per second and is stored in the buffer 1660. In one embodiment, the buffer 1660 is one large SRAM buffer used to store data from all memory die. In another embodiment, the buffer 1660 comprises separate SRAM buffers for each memory die. While in the buffer 1660, the data can be operated on by the memory manager 1670 (e.g., ECC decoding) and then provided to the GPU interface 1608. In other embodiments, the buffer 1660 can comprise multiple buffers for each memory die. The buffer 1660 and the memory manager 1670 are part of the memory processing/management 1606.

In one embodiment, data is received by the memory controller 1602 from the stack of memory die 700 (e.g., MD 0, MD 1, MD 2, . . . MD 31) during a read process at a higher bandwidth than data is reported to the GPU 1610 by the GPU Interface 1608, such that the received data is buffered in the memory controller 1602 between reception at the memory controller 1602 and reporting to the GPU 1610. This time gap between reception of data and reporting data (e.g., due to different throughputs) allows time for performing the ECC decoding and error correction. In some embodiments, the time gap is also large enough to allow data to be refreshed in the memory die (as explained below).

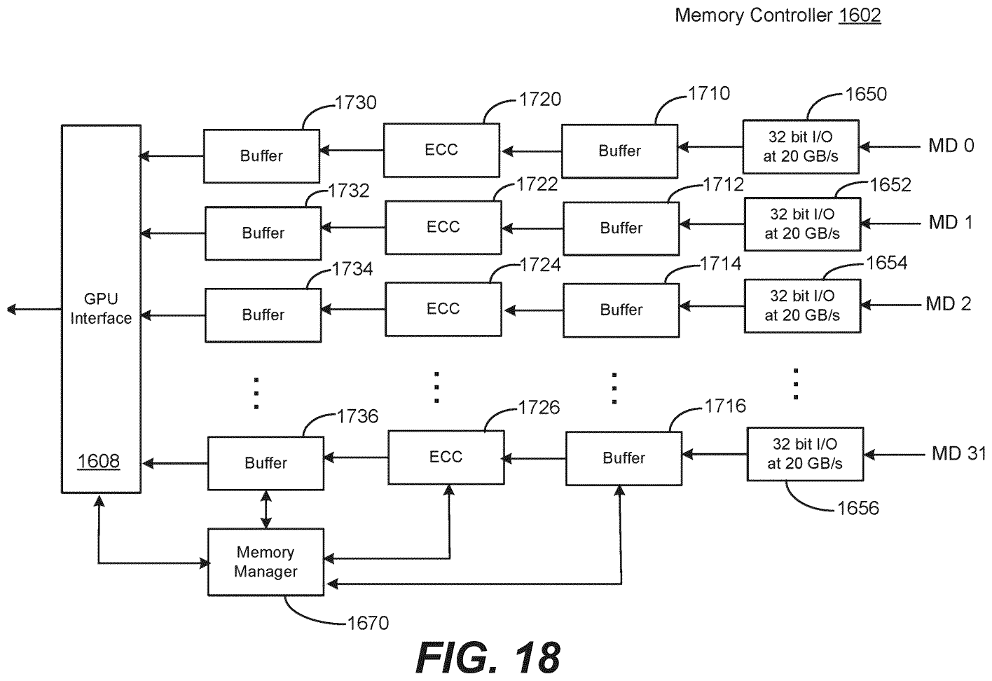

FIG. 18 is a block diagram depicting error correction performed at the memory controller during a high bandwidth read process. Data received from thirty two memory die (MD 0, MD 1, MD 2, . . . MD 31) at separate interface circuits (1650, 1652, 1654, . . . 1656) for each memory die is provided to separate buffers (1710, 1712, 1714, . . . 1716) for each memory die. From the separate buffers (1710, 1712, 1714, . . . 1716) for each memory die, separate ECC engines (1720, 1722, 1724, . . . 1726) for each memory die perform ECC decoding (which may include correcting one or more errors in the data). In one embodiment, an ECC code word can be 1 KB-2 KB. The output of the separate ECC engines (1720, 1722, 1724, . . . 1726) is provided to separate output buffers (1730, 1732, 1734, . . . 1736) for each memory die. In one embodiment, the buffers are SRAM. In one embodiment, instead of having separate buffers for each memory die (before and/or after the ECC), one buffer can be used for all memory die (e.g., with different portions of the buffer used for different memory die). In one embodiment, each of the buffers depicted in FIG. 18 is 64 KB; however, other embodiments can use larger buffers. On one embodiment, memory manager 1670 is connected to each of the components of FIG. 18 for managing the data flow and ECC operations.

In one embodiment, extra data protection beyond ECC is implemented using XOR. For example, a number of pages of data are XOR'd together and the result (referred to as the XOR result, which is an example of ECC data) is stored in the non-volatile memory. When reading data, if an error is found in the data read then the correct data can be obtained by XORing the XOR result with all of the pages except the page with the error. The XOR result can be stored anywhere in any of the memory dies. In one embodiment, the XOR result is stored on the same memory die as the pages used to create the XOR result. In another embodiment, the XOR result is created from pages of different memory die.

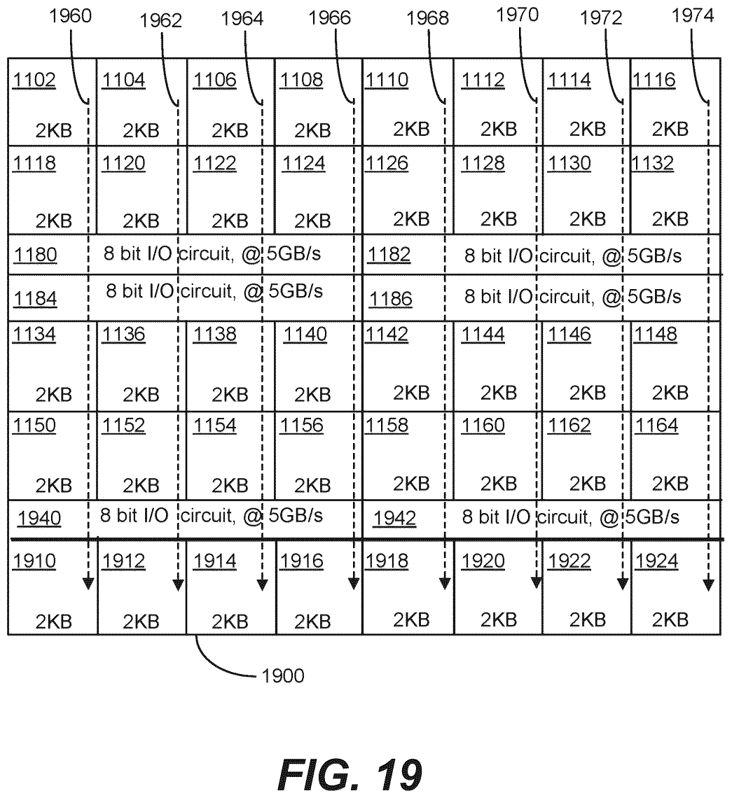

FIG. 19 is a block diagram depicting a partial floor plan 1900 for a memory die that shows one example of where to store the XOR result. The floor plan of FIG. 19 is similar to the floor plan of FIG. 11, but with the addition of planes 1910, 1912, 1914, 1916, 1918, 1920, 1922, and 1924, each of which stores 2K Bytes per page. The floor plan of FIG. 19 also includes I/O circuit 1940 and I/O circuit 1942. I/O circuit 1940 has an 8 bit data bus and provides for communicating data between the memory controller 704 and planes 1910, 1912, 1914, and 1916 at 5 GB per second via 8 TSVs. I/O circuit 1942 has an 8 bit data bus and provides for communicating data between the memory controller 704 and planes 1918, 1920, 1922, and 1924 at 5 GB per second via 8 TSVs. In the embodiment of FIG. 19, data from corresponding pages in planes 1102, 1118, 1134, and 1150 are XOR's together, and the resulting XOR data (data protection data) is stored in a corresponding page of plane 1910 (as per arrow 1960); data from corresponding pages in planes 1104, 1120, 1136, and 1152 are XOR's together and the resulting XOR data (ECC data) is stored in a corresponding page of plane 1912 (as per arrow 1962); data from corresponding pages in planes 1106, 1122, 1138, and 1154 are XOR's together and the resulting XOR data (data protection data) is stored in a corresponding page of plane 1914 (as per arrow 1964); data from corresponding pages in planes 1108, 1124, 1140, and 1156 are XOR's together and the resulting XOR data (ECC data) is stored in a corresponding page of plane 1916 (as per arrow 1966); data from corresponding pages in planes 1110, 1126, 1142, and 1158 are XOR's together and the resulting XOR data (ECC data) is stored in a corresponding page of plane 1918 (as per arrow 1968); data from corresponding pages in planes 1112, 1128, 1144, and 1160 are XOR's together and the resulting XOR data (ECC data) is stored in a corresponding page of plane 1920 (as per arrow 1970); data from corresponding pages in planes 1114, 1130, 1146, and 1162 are XOR's together and the resulting XOR data (ECC data) is stored in a corresponding page of plane 1922 (as per arrow 1972); and data from corresponding pages in planes 1116, 1132, 1148, and 1162 are XOR's together and the resulting XOR data (ECC data) is stored in a corresponding page of plane 1924 (as per arrow 1974). In the embodiment of FIG. 19, ECC requires 25% overhead (as four 2 KB pages are used to add one extra 2 KB page).

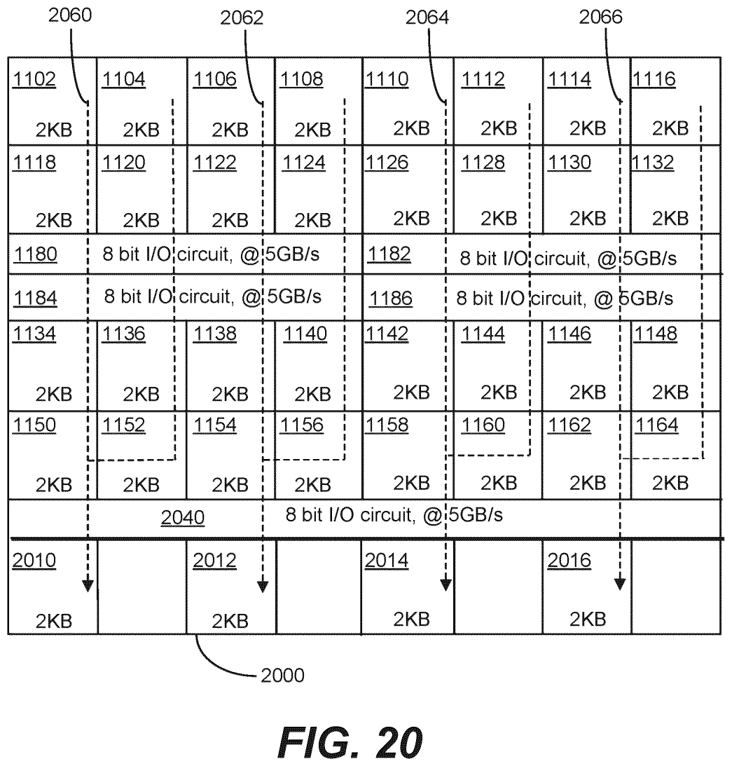

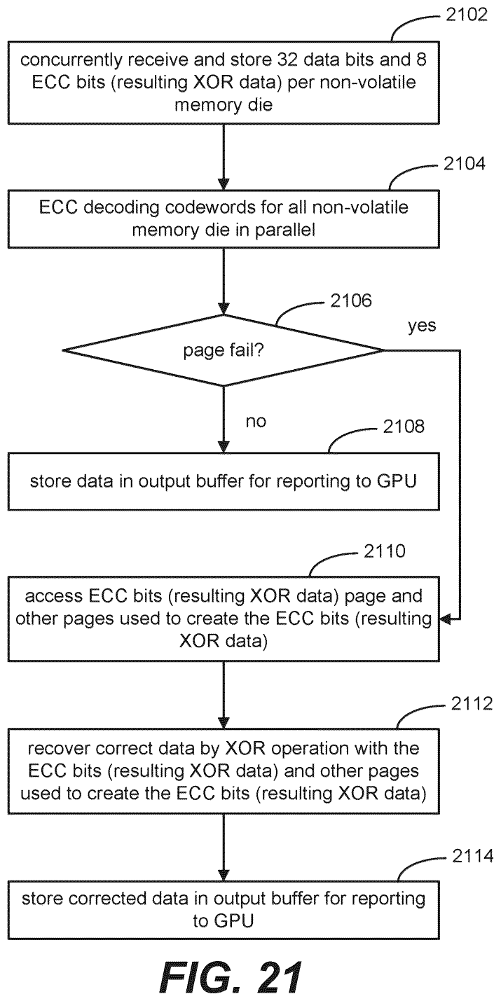

FIG. 20 is a block diagram depicting a partial floor plan 2000 for a memory die that shows one example of where to store the XOR result. The floor plan of FIG. 20 is similar to the floor plan of FIG. 11, but with the addition of planes 2010, 2012, 2014, and 2016, each of which stores 2K Bytes per page. The floor plan of FIG. 20 also includes I/O circuit 2040, which has an 8 bit data bus and provides for communicating data between the memory controller 704 and planes 1910, 1912, 1914, and 1916 at 5 GB per second via 8 TSVs. I/O circuit 1942 has an 8 bit data bus and provides for communicating data between the memory controller 704 and planes 2010, 2012, 2014, and 2016 at 5 GB per second.

In the embodiment of FIG. 20, data from corresponding pages in planes 1102, 1118, 1134, 1150, 1104, 1120, 1136, and 1152 are XOR's together and the resulting XOR data (data protection data) is stored in a corresponding page of plane 2010 (as per arrow 2060); data from corresponding pages in planes 1106, 1122, 1138, 1154, 1108, 1124, 1140, and 1156 are XOR's together and the resulting XOR data (ECC data) is stored in a corresponding page of plane 2012 (as per arrow 2062); data from corresponding pages in planes 1110, 1126, 1142, 1158, 1112, 1128, 1144, and 1160 are XOR's together and the resulting XOR data (ECC data) is stored in a corresponding page of plane 2014 (as per arrow 2064); and data from corresponding pages in planes 1114, 1130, 1146, 1162, 1116, 1132, 1148, and 1162 are XOR's together and the resulting XOR data (ECC data) is stored in a corresponding page of plane 2016 (as per arrow 2066). In the embodiment of FIG. 20, ECC required 12.5% overhead (as eight 2 KB pages are used to add one extra 2 KB page).

FIG. 21 is a flow chart describing one embodiment of a process for performing error correction during a high bandwidth read process. The process of FIG. 21 can be used with the structures of FIG. 19 or 20, as well as other structures adapted to add planes or other space for storing resulting XOR data (data protection data). In step 2102 of FIG. 21, the memory controller 704 (illustrated in FIG. 7) concurrently receives and stores 32 data bits and 8 extra protecting bits (resulting XOR data) per non-volatile memory die via forty TSVs per memory die I/O circuit. In step 2104, the memory controller 704 performs ECC decoding of the codewords sensed by the memory die and received in step 2102, for all non-volatile memory die in parallel. If none of the pages failed the ECC decoding process of step 2104 (step 2106) then the decoded data is stored in one or more output buffers in the memory controller 704 for reporting to the GPU in step 2108. If a page failed the ECC decoding process of step 2104 (step 2106), then in step 2110, the memory controller 704 accesses the ECC bits (resulting XOR data) for the failed page and the other pages used to create the ECC bits (resulting XOR data). In step 2112, the memory controller 704 recovers the correct data by an XOR operation with the ECC bits (resulting XOR data) and other pages used to create the ECC bits (resulting XOR data). In step 2114, the memory controller 704 stores the corrected data in one or more output buffers for reporting to the GPU.

Due to read disturb, data retention issues or other issues, some of the threshold voltages of the memory cells storing data in the memory die may shift. To prevent uncorrectable errors, the system will periodically refresh the data before there are too many errors in the data. In one embodiment, refreshing the data includes reading the data in the memory cells of a memory block that has suffered read disturb and re-programming the same data into the memory cells of another memory block. In another embodiment, refreshing the data means reading the data, using ECC bits (resulting XOR data) to correct the errors and then re-programming the corrected data. Typically, the data is re-programmed to a new location. However, in some embodiments it may be possible to re-program to the same location (e.g., erase and then re-program).

The refreshing of data can be automatically performed based on the passing of an interval. For example, after the data is read X times (e.g., X=1K, 10K, 100K or 1 million), the data is refreshed. Alternatively, after Y days (or weeks or months) the data can automatically be refreshed. In another embodiment, the data can be refreshed after a reading of the data that was successful, however, the ECC process came close to failing (e.g., if the ECC process can correct M bits and during the most recent read process M−1 bits were corrected).

In one example implementation, data that needs to be refreshed will be marked for refreshing (e.g., store list of blocks that need to be refreshed). Then the system can refresh the marked block during system idle time, e.g., when the system is not used at night or at another time period during the day, or when there is a time during the day when a lower bandwidth is used so that some of the resources of the memory can be used for data refreshing.

In another embodiment, the bandwidth or throughput of data from the stack of memory dies to the memory controller is faster/greater than the bandwidth or throughput of data from the memory controller to the GPU/host, so that there is a time gap for which the data is in one or more buffers in the memory controller and during that time gap some or all of the data refreshing can be performed, or the bandwidth or throughput of data from the stack of memory dies to the memory controller can be reduced to match the bandwidth or throughput of data from memory controller to the GPU/host so that some of the resources of the memory controller, memory dies, and I/O circuits can be used for refreshing data.

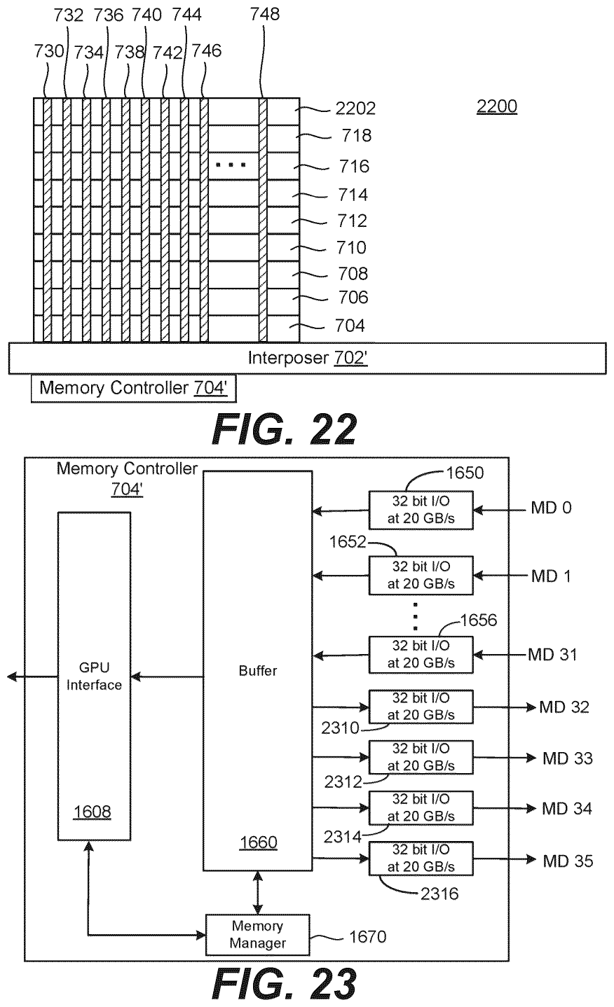

In some embodiments, the refreshing of data comprises re-programming the data (with or without error correction) to a new location in memory. One example implementation adds a new layer to the stack of memory dies, such that the new layer includes four additional memory die (e.g., as per FIG. 8A or 8B). This example implementation is depicted in FIG. 22, which shows memory system 200 having stack of layers 704, 706, 708, 710,712, 714, 716, and 718 (see FIG. 7) and additional layer 2202 (which is in the form of FIG. 8A or 8B) having four additional memory die. Data that is refreshed will be programmed to one of the memory die on layer 2202. FIG. 22 shows the memory controller 704′ beneath the interposer 702′ and directly below the stack of layers 704, 706, 708, 710,712, 714, 716, 718, and 2202. In another embodiment, there is no interposer and the memory controller 704′ connects directly to the memory die. In another embodiment (with or without an interposer), the memory controller 704′ is positioned beside the stack of layers 704, 706, 708, 710,712, 714, 716, 718, and 2202. Each of the layers may include four dies constructed according to any of the embodiments of FIGS. 9-13 discussed above.

FIG. 23 depicts the data flow for the memory controller 704′ for communicating with layers 704, 706, 708, 710,712, 714, 716, 718, and 2202 during a high bandwidth read process that includes refreshing data during the high bandwidth read process. As discussed above, during the high bandwidth read process data is received from the thirty two memory dies MD 0-MD 31 on layers 704, 706, 708, 710,712, 714, 716, and 718 at I/O circuits 1650, 1652, . . . 1656. Data received at the memory controller that needs to be refreshed will be re-programmed by sending that data for programming to one of memory dies MD 32, MD 33, MD 34 or MD 35 via I/O circuits 2310, 2312, 2314 or 2316 (respectively). Each of I/O circuits 2310, 2312, 2314 or 2316 communicate 32 bits in parallel at 20 GB per second using TSVs (as discussed above).

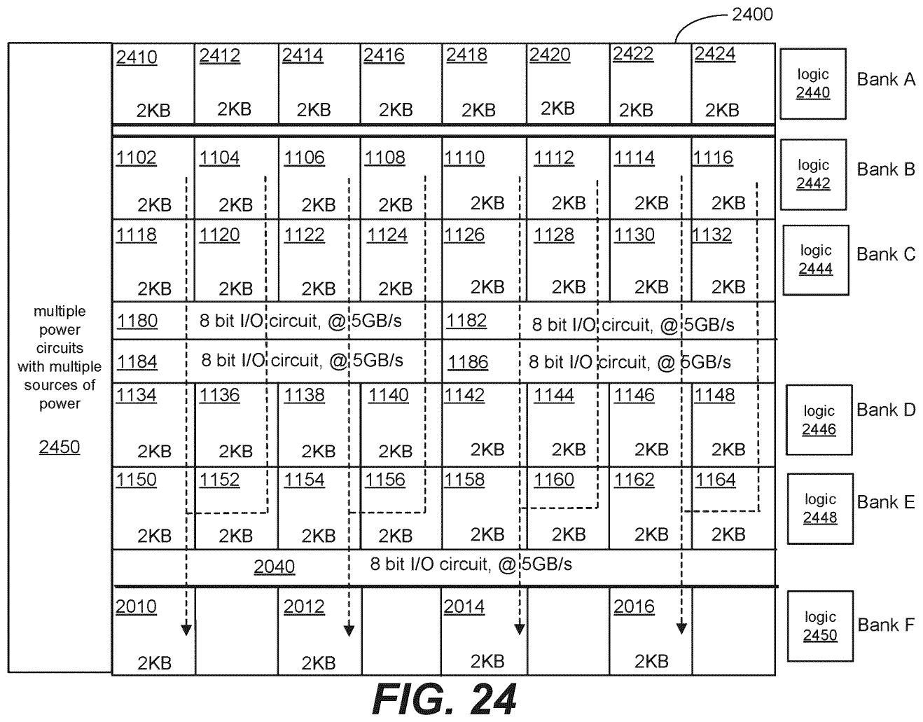

FIG. 24 depicts a floor plan of a memory die 2400 for an embodiment that refreshes data by re-programming the data (during idle time or while performing a high bandwidth read process as discussed above) to an additional bank of planes on the same memory die. The refreshing can be performed by reading the data to the memory controller and then re-programming back to the same (or different) memory die. Alternatively, the refreshing can be performed by reading the data on the memory die, temporarily storing the data on the memory die, (optionally) correcting errors on the memory die (e.g., using an ECC engine added to System Control Logic 208) and then re-programming back to the same memory die (without the data leaving the Memory Die and without the data being transmitted to the Memory Controller)—sometimes referred to as an On-Chip Copy.

The floor plan of FIG. 24 is similar to the floor plan of FIG. 20, but with the addition of planes 2410, 2412, 2414, 2416, 2418, 2420, 2422, and 2424, each of which stores 2K Bytes per page and can use I/O circuits 1180, 1182, 1184 and/or 1186. The floor plan of FIG. 24 also includes separate logic (electrical circuits) for each bank of planes that is responsible for performing programming and reading such that each bank can be separately and concurrently programmed or read. For example, logic 2440 controls programming and reading for Bank A (planes 2410-2424), logic 2442 controls programming and reading for Bank AB (planes 1102-1116-2424), logic 2444 controls programming and reading for Bank C (planes 1118-1132), logic 2446 controls programming and reading for Bank D (planes 1134-1148), logic 2447 controls programming and reading for Bank E (planes 1150-1164), and logic 2450 controls programming and reading for Bank F (planes 2010-2016-2424). The floor plan of FIG. 24 also includes multiple power circuits 2450 with multiple sources of power (e.g., one power circuit with one or more sources of power for each bank) to support each bank being separately and concurrently programmed or read. In one embodiment, and any bank can be used to store data and any other bank can be used to store reprogrammed data that has been refreshed.

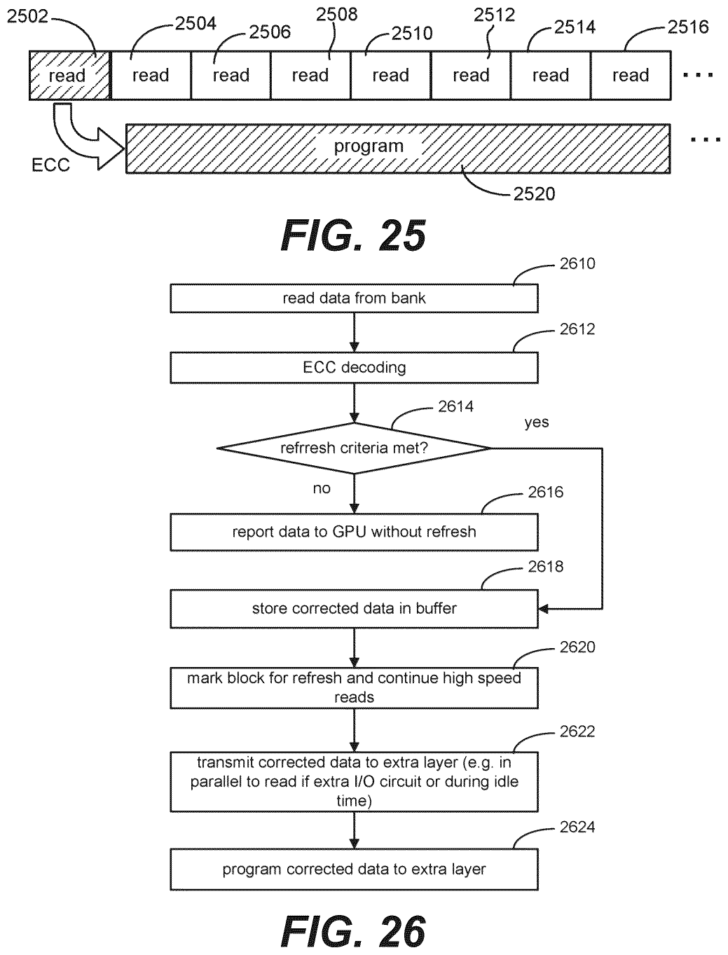

FIG. 25 is a timing diagram for performing a data refresh, as per the embodiment of FIG. 24. The top row of FIG. 25 shows the timing for units of data (e.g., pages, blocks, etc.) 2502, 2504, 2506, 2508, 2510, 2512, 2514, 2516, . . . that are read serially and transmitted to the memory controller. It is determined that the refresh criteria has been met for a unit of data 2502 (e.g., because of time duration, number of reads, ECC almost failing, etc.—as discussed above); therefore, data 2502 will be re-programmed. The embodiment shows data 2502 being decoded using the ECC process to fix errors and then being re-programmed during time slot 2520 concurrently with the reading of data units 2504, 2506, 2508, 2510, 2512, 2514, and 2516.

FIG. 26 is a flow chart describing one embodiment of a process for performing a data refresh in conjunction with a high bandwidth read process. The method of FIG. 26 implements an embodiment in which the refreshing of data is performed by the memory controller (e.g., see FIGS. 22 and 23). In step 2610, data is read from a bank of planes on a memory die and transmitted to the memory controller. In step 2612, the memory controller performs ECC decoding of the data read. If (step 2614) the refresh criteria is not met (meaning no need for a data refresh), then the data is reported to the GPU from the memory controller in step 2616. In some embodiments, as discussed above, the refresh criteria is met after a time duration, number of reads, ECC almost failing, etc. If (in step 2614) the refresh criteria has been met, then in step 2618 the memory controller will store the data to be refreshed in a buffer (e.g., buffer 1660 of FIG. 17). The block from which the data was read is marked for refresh (e.g., by adding it to a list of blocks to be refreshed) in step 2620. In some embodiments, errors in the data will be corrected during the ECC decoding process. In step 2622, the corrected data is transmitted to the extra layer (e.g., layer 2202 of FIG. 22) in parallel (concurrently) to the read process if there is an extra I/O circuit (e.g., 2310-2314) or during idle time (as discussed above). In step 2624, the corrected data is programmed to the extra layer (e.g., layer 2202 of FIG. 22) in parallel (concurrently) to read process if there is an extra I/O circuit (e.g., 2310-2314) or during idle time (as discussed above).

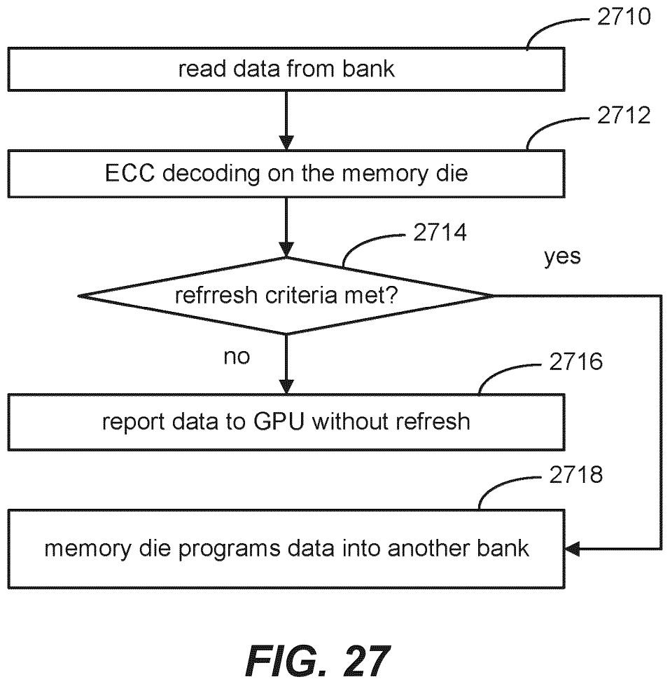

FIG. 27 is a flow chart describing one embodiment of a process for performing a data refresh in conjunction with a high bandwidth read process. The method of FIG. 27 implements an embodiment in which the refreshing of data is performed by the memory die (e.g., see FIGS. 24 and 25). In step 2710, data is read from a bank on a memory die and stored on that same memory die (e.g., in SRAM or in latches at the sense amplifiers). In step 2712, ECC decoding of the data read is performed on the memory die (e.g., using an ECC engine added to the system control logic 208 of FIGS. 2A and 2B or using the state machine). In some embodiments, the ECC decoding fixes errors in the data. Ion some embodiments, the memory die does not perform ECC decoding. If the refresh criteria have not been met (step 2714) then the data is reported to the GPU via the memory controller. If the refresh criteria has been met (step 2714), then the memory die programs the data into another bank (different from the bank that the data was read from).

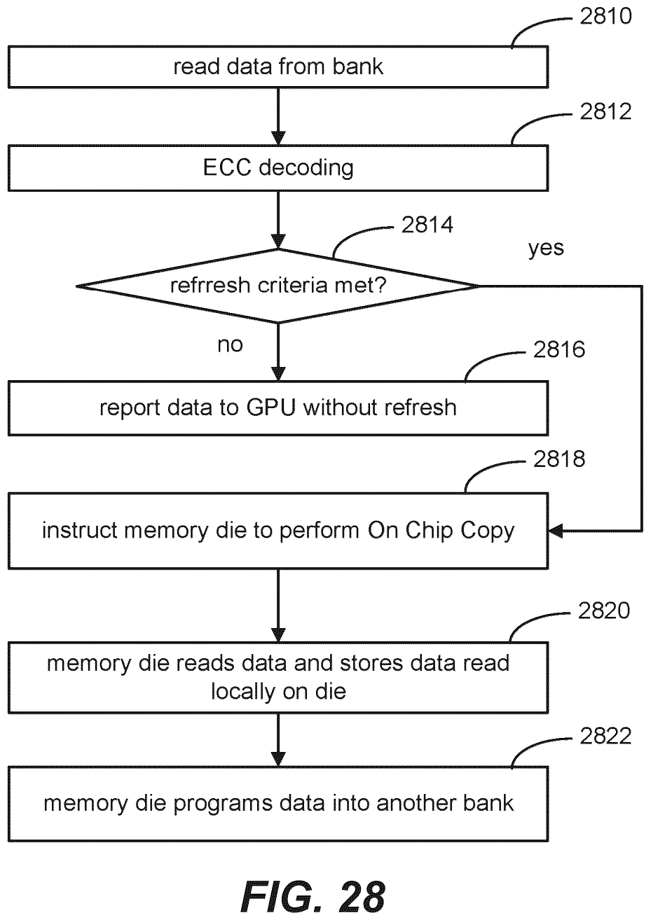

FIG. 28 is a flow chart describing one embodiment of a process for performing a data refresh in conjunction with a high bandwidth read process. The method of FIG. 28 implements an embodiment in which the refreshing of data is performed by the memory die based on the structures of FIGS. 22-24. In step 2810, data is read from a bank on a memory die and transmitted to the memory controller. In step 2812, the memory controller performs ECC decoding of the data read. If (step 2814) the refresh criteria is not met (meaning no need for a data refresh), then the data is reported to the GPU from the memory controller in step 2816. If (in step 2814) the refresh criteria has been met, then in step 2818 the memory controller will instruct the memory die from which the data was read to perform an On-Chip Copy. In response to the instruction of step 2818, the memory die reads the data again and stores it locally on the memory die (e.g., in local SRAM or in latches at the sense amplifiers). In step 2822, the memory die programs the data into another bank. In some embodiments, data can be refreshed a page at a time, a block at a time, a plane at a time or a bank of planes at a time.

A non-volatile memory has been proposed that can perform a high bandwidth read process.

One embodiment includes a non-volatile memory apparatus, comprising: a stack of memory dies comprising multiple layers, each layer comprising multiple memory die, the stack includes separate parallel TSV's for each memory die; an interposer connected to the separate parallel TSVs for each memory die; and a memory controller connected to the interposer and configured to perform a high bandwidth read process for data stored in the stack across all or multiple of the memory dies.

In one example implementation, each memory die comprises multiple planes (arrays), groups of planes form banks, each memory die has multiple I/O circuits such that there is one I/O circuit per bank, the stack includes separate parallel TSV's for each I/O circuit of each memory die.

In one example implementation, the controller includes separate input paths for each memory die in communication with respective TSVs and one or more SRAM buffers connected to the separate input paths.

In one example implementation, the controller includes separate input paths for each memory die in communication with respective TSVs, separate and parallel ECC processing paths for each memory die connected to the separate input paths to perform ECC decoding concurrently for each memory die and one or more SRAM buffers connected to the and parallel ECC processing paths.

In one example implementation, each of the memory dies include an extra bank; and the memory controller is configured to perform a refresh of data to the extra bank during idle time or concurrently with the high bandwidth read process.

In one example implementation, the stack includes an extra layer; and the memory controller is configured to perform a refresh of data to the extra layer during idle time or concurrently with the high bandwidth read process.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A non-volatile memory apparatus, comprising:
a stack of memory dies comprising multiple layers, each layer comprising multiple memory die, the stack includes separate parallel through silicon vias (TSVs) for each memory die; and
a memory controller in electrical communication with the separate parallel TSVs for each memory die and configured to perform a high bandwidth read process for data stored in the stack across all or multiple of the memory dies.

2. The non-volatile memory apparatus of claim 1, further including an interposer that is connected to the separate parallel TSVs for each memory die and to the memory controller.

3. The non-volatile memory apparatus of claim 1, wherein:
each memory die comprises multiple planes,
groups of planes form banks,
each memory die has multiple input/output (I/O) circuits such that there is one I/O circuit per bank,
the stack includes separate parallel TSVs for each I/O circuit of each memory die, and
the memory controller includes separate input paths for each memory die in communication with respective TSVs and one or more static random access memory (SRAM) buffers connected to the separate input paths.

4. The non-volatile memory apparatus of claim 1, wherein:
the memory controller includes separate input paths for each memory die in communication with respective TSVs, separate and parallel error correction code (ECC) processing paths for each memory die connected to the separate input paths to perform ECC decoding concurrently for each memory die and one or more static random access memory (SRAM) buffers connected to the and parallel ECC processing paths.

5. The non-volatile memory apparatus of claim 1, wherein:
each of the memory dies include an extra bank; and
the memory controller is configured to perform a refresh of data to the extra bank during idle time or concurrently with the high bandwidth read process.

6. The non-volatile memory apparatus of claim 1, wherein:
the stack includes an extra layer; and
the memory controller is configured to perform a refresh of data to the extra layer during idle time or concurrently with the high bandwidth read process.

7. The non-volatile memory apparatus of claim 1, wherein each memory die comprises at least sixteen planes that are grouped into at least four banks, and wherein each bank includes an input/output (I/O) circuit for communicating data between the planes and the memory controller.

8. A method of operating a non-volatile memory apparatus, comprising the steps of:
preparing a stack of memory dies comprising multiple layers, each layer comprising multiple memory die, the stack includes separate parallel through silicon vias (TSVs) for each memory die, an interposer connected to the separate parallel TSVs for each memory die, and a memory controller connected to the interposer; and
performing a high bandwidth read process for data stored in the stack across all or multiple of the memory dies.

9. The method of claim 8, wherein:
each memory die comprises multiple planes,
groups of planes form banks,
each memory die has multiple input/output (I/O) circuits such that there is one I/O circuit per bank, and
the stack includes separate parallel TSVs for each I/O circuit of each memory die.

10. The method of claim 8, wherein:
the memory controller includes separate input paths for each memory die in communication with respective TSVs and one or more static random access memory (SRAM) buffers connected to the separate input paths.

11. The method of claim 8, wherein:
the memory controller includes separate input paths for each memory die in communication with respective TSVs, separate and parallel error correction code (ECC) processing paths for each memory die connected to the separate input paths to perform ECC decoding concurrently for each memory die and one or more static random access memory (SRAM) buffers connected to the and parallel ECC processing paths.

12. The method of claim 8, wherein:
each of the memory dies include an extra bank; and
the memory controller is configured to perform a refresh of data to the extra bank during idle time or concurrently with the high bandwidth read process.

13. The method of claim 8, wherein:
the stack includes an extra layer; and
the memory controller is configured to perform a refresh of data to the extra layer during idle time or concurrently with the high bandwidth read process.

14. The method of claim 8, wherein each memory die comprises at least sixteen planes that are grouped into at least four banks, and wherein each bank includes an input/output (I/O) circuit for communicating data between the planes and the memory controller.

15. A computing system, comprising:
a processor unit;
a plurality of high bandwidth flash packages in electrical communication with the processor unit; and
each of the high bandwidth flash packages including;
a stack of memory dies comprising multiple layers, each layer comprising multiple memory die, the stack includes separate parallel through silicon vias (TSVs) for each memory die,
an interposer connected to the separate parallel TSVs for each memory die, and
a memory controller connected to the interposer and configured to perform a high bandwidth read process for data stored in the stack across all or multiple of the memory dies.

16. The computing system as set forth in claim 15, wherein the high bandwidth flash packages include data related to large language model weight matrices.

17. The computing system of claim 15, wherein:
each memory die comprises multiple planes,
groups of planes form banks,
each memory die has multiple input/output (I/O) circuits such that there is one I/O circuit per bank, and
the stack includes separate parallel TSVs for each I/O circuit of each memory die.

18. The computing system of claim 15, wherein:
the memory controller includes separate input paths for each memory die in communication with respective TSVs and one or more static random access memory (SRAM) buffers connected to the separate input paths.

19. The computing system of claim 15, wherein:
the memory controller includes separate input paths for each memory die in communication with respective TSVs, separate and parallel error correction code (ECC) processing paths for each memory die connected to the separate input paths to perform ECC decoding concurrently for each memory die and one or more static random access memory (SRAM) buffers connected to the and parallel ECC processing paths.

20. The computing system of claim 15, wherein:
each of the memory dies include an extra bank; and
the memory controller is configured to perform a refresh of data to the extra bank during idle time or concurrently with the high bandwidth read process.
